(19) United States
(12) Patent Application Publication
(10) Pub. No.: US 2024/0329146 A1
(43) Pub. Date: Oct. 3, 2024

(54) IMPROVED BATTERIES, CELLS, COMPONENTS, AND TESTING THEREOF

(71) Applicant: Celgard, LLC, Charlotte, NC (US)

(72) Inventors: Zhengming Zhang, Rock Hill, SC (US); Wenbin Yin, Charlotte, NC (US)

(21) Appl. No.: 18/580,136

(22) PCT Filed: Jul. 13, 2022
(86) PCT No.: PCT/US2022/036910

§ 371 Date: Jan. 17, 2024

Related U.S. Application Data
(60) Provisional application No. 63/225,211, filed on Jul. 23, 2021.
(60) Provisional application No. 63/230,484, filed on Aug. 6, 2021.
(60) Provisional application No. 63/233,085, filed on Aug. 13, 2021.
(60) Provisional application No. 63/242,709, filed on Sep. 10, 2021.

(51) Int. Cl. G01R 31/389; H01M 10/0525; H01M 10/42; H01M 50/417; H01M 50/449; H01M 50/491

(52) U.S. Cl. CPC G01R 31/389; H01M 10/0525; H01M 10/4285; H01M 50/417; H01M 50/449; H01M 50/491

(57) ABSTRACT

In one aspect, a method of measuring the internal short resistance of a battery separator comprising one or more layers of a polyolefin is provided. A method comprises applying a force via a force component comprising a ball to a test stack, the test stack comprising an anode, a separator, and a cathode, deforming the test stack until an electrical short occurs, and determining an ISR value for the separator, the value corresponding to an overall ISR, or at least in one of the MD, TD, or Z-direction.

### RELATED APPLICATION DATA

The present application claims the benefit of U.S. PCT Application No. PCT/US2022/036910, filed Jul. 13, 2022, which claims priority to U.S. Provisional Patent Application Ser. No. 63/225,211 filed Jul. 23, 2021, to U.S. Provisional Patent Application Ser. No. 63/230,484, filed Aug. 6, 2021, to U.S. Provisional Patent Application Ser. No. 63/233,085, filed Aug. 13, 2021, and to U.S. Provisional Patent Application Ser. No. 63/242,709, filed Sep. 10, 2021, each of which is incorporated herein by reference in its entirety.

### FIELD

The technology described herein generally relates to films, thin films, membranes, dry process polyolefin membranes, coated membranes, separators, coated separators, batteries and/or cells, lithium batteries and/or cells, battery and/or cell components, and methods or devices for making, testing, and/or using the same.

### BACKGROUND

Battery separators are microporous membranes that, among other roles, form physical barriers positioned between the cathode and anode of a battery to prevent these electrodes from physically contacting and causing, for instance, a short circuit. In a battery, cell or battery or cell's operation, the electrodes of a battery or cell swell and contract which in turn can apply pressure on a separator and affect a battery or cell's performance.

Accordingly, there is a need for improved membranes, separators, cathodes, battery or cells, battery or cell components, and the testing thereof, that exhibit higher performance characteristics and additionally impart improved safety features over conventional battery or cells and battery or cell components.

### SUMMARY

This summary is provided to introduce a selection of concepts in a simplified form that are further described below in the detailed description. This summary is not intended to identify key features or essential features of the claimed subject matter, nor is it intended to be used in isolation as an aid in determining the scope of the claimed subject matter.

Embodiments of the technology described herein are directed towards batteries or cells and components thereof, for instance anodes, cathodes, and separators or microporous membranes. Further embodiments of the technology described herein are directed towards apparatus, methods, and/or processes for the testing of batteries or cells and/or components thereof such as separators or membranes.

According to some embodiments, a method of measuring the internal short resistance of a battery separator comprising one or more layers of a polyolefin is provided. A method comprises applying a force via a force component comprising a ball to a test stack, the test stack comprising an anode, a separator, and a cathode, deforming the test stack until an electrical short occurs, and determining an ISR value for the separator, the value corresponding to an overall ISR, or at least in one of the MD, TD, or Z-direction.

In some further embodiments, a wetting test apparatus and method are provided for testing the wetting of a battery separator. In embodiments, a wetting test apparatus comprises a chamber comprising an electrolyte injection port, a pair of conductive blocks within the chamber and biased towards each other via a spring, a separator stack held between the blocks under pressure, and an impedance or LCR device in communication with the conductive blocks. A method for testing a separator via the apparatus may comprise releasing electrolyte into the chamber to wet out the separator stack, determining a frequency associated with the separator stack via the impedance device, setting the frequency and the voltage, and determining an impedance associated with the separator stack over a time period.

According to some other embodiments, a battery separator is provided comprising a microporous membrane comprising one or more layers of a polyolefin, wherein the microporous membrane has an electrical resistance (ER) of less than 10 Ω/mm at a compression pressure of 1,000 lbs, has an electrical resistance of less than 25 Ω/mm at a compression pressure of 5,000 lbs, an electrical resistance of less than 37 Ω/mm at a compression pressure of 7,500 lbs, and/or an electrical resistance of less than 47 Ω/mm at a compression pressure of 10,000 lbs.

In some even other embodiments, a battery separator is provided comprising a microporous membrane comprising one or more layers of a polyolefin, wherein the microporous membrane exhibits a compression from about 5% to about 10% under a stress of 8 N/mm², and wherein the microporous membrane exhibits an elastic recovery from 50% to 100%. In some instances, the microporous membrane exhibits a compression from about 6% to about 10% under a stress of 8 N/mm², and wherein the microporous membrane exhibits an elastic recovery of at least 50%, at least 60%, at least 70%, at least 80%, at least 90%, and/or from 95% to 100%.

In some even further embodiments, a battery is provided, for example a cylindrical battery, comprising an anode, a cathode, and a separator, wherein the cathode comprises a rounded edge portion and/or comprises a polymer coated cathode edge.

Additional objects, advantages, and novel features of the invention will be set forth in part in the description which follows, and in part will become apparent to those skilled in the art upon examination of the following or can be learned by practice of the invention.

### BRIEF DESCRIPTION OF THE DRAWINGS

Aspects of the technology presented herein are described in detail below with reference to the accompanying drawing figures, wherein:

FIG. 1 illustrates an electrical resistance versus applied pressure curve of a separator or microporous membrane, in accordance with some embodiments of the technology described herein;

FIG. 2 illustrates a pressure resistance and elasticity curve of a separator or microporous membrane, in accordance with some embodiments of the technology described herein;

FIG. 3 shows an example schematic of a battery, in accordance with some embodiments of the technology described herein;

FIG. 4A and FIG. 8 each illustrates an example internal short resistance (ISR) test and related apparatus, in accordance with some embodiments of the technology described herein;

FIG. 4B and FIG. 9 each illustrates an example short circuit through a separator, in accordance with some embodiments of the technology described herein;

FIG. 5A and FIG. 10 each illustrates example ISR testing for battery separators, in accordance with some embodiments of the technology described herein;

FIG. 5B and FIG. 11 each illustrates example ISR testing for battery separators, in accordance with some embodiments of the technology described herein;

FIG. 6A illustrates example wetting testing apparatus and methods, in accordance with some embodiments of the technology described herein;

FIG. 6B illustrates example wetting testing apparatus and methods, in accordance with some embodiments of the technology described herein;

FIG. 7 illustrates compression curves of example separators or microporous membranes, in accordance with some embodiments of the technology described herein;

FIG. 12 illustrates a classic film strength measurement test (X and Y) of puncture resistance;

FIG. 13 are images related to Oxidation Resistance: PP vs. PE separators;

FIG. 14 are images and graphs on Longer Cycle Life due to PP Oxidation Resistance;

FIG. 15 are images and graphs on Compression Resistance: Extended Cell Longevity and Safety of dry process separators;

FIG. 16 illustrates Celgard Dry Separator Mechanical Strength: Puncture Strength vs. Internal Short Resistance testing (part 1);

FIG. 17 illustrates Celgard Dry Separator Mechanical Strength: Film Puncture Strength vs. Internal Short Resistance Test (part 2);

FIG. 18 are images on Reducing Dendrite Formation/Mitigating Metal Contamination;

FIG. 19 are images on Improved Manufacturability During Lamination Process with Thin Adhesive Coating;

FIG. 20 are images on Improved Safety with Thin High Thermal Stability (HTS) Ceramic Technology; and,

FIG. 21 are images and graphs on Manufacturing Efficiency:

Cost Effective and Low Carbon Footprint of dry process membranes or separators, in accordance with some embodiments of the technology described herein.

### DETAILED DESCRIPTION

The subject matter of aspects of the present disclosure is described with specificity herein to meet statutory requirements. However, the description itself is not intended to limit the scope of this patent. Rather, the inventors have contemplated that the claimed subject matter might also be embodied in other ways, to include different steps or combinations of steps similar to the ones described in this document, in conjunction with other present or future technologies. Moreover, although the terms “step” and/or “block” can be used herein to connote different elements of methods employed, the terms should not be interpreted as implying any particular order among or between various steps disclosed herein unless and except when the order of individual steps is explicitly described.

Embodiments described herein can be understood more readily by reference to the following detailed description, examples, and figures. Elements, apparatus, and methods described herein, however, are not limited to the specific embodiments presented in the detailed description, examples, and figures. It should be recognized that the exemplary embodiments herein are merely illustrative of the principles of the invention. Numerous modifications and adaptations will be readily apparent to those of skill in the art without departing from the spirit and scope of the invention.

In addition, all ranges disclosed herein are to be understood to encompass any and all subranges subsumed therein. For example, a stated range of “1.0 to 10.0” should be considered to include any and all subranges beginning with a minimum value of 1.0 or more and ending with a maximum value of 10.0 or less, e.g., 1.0 to 5.3, or 4.7 to 10.0, or 3.6 to 7.9.

All ranges disclosed herein are also to be considered to include the end points of the range, unless expressly stated otherwise. For example, a range of “between 5 and 10” or “5 to 10” or “5-10” should generally be considered to include the end points 5 and 10.

Further, when the phrase “up to” is used in connection with an amount or quantity; it is to be understood that the amount is at least a detectable amount or quantity. For example, a material present in an amount “up to” a specified amount can be present from a detectable amount and up to and including the specified amount.

Additionally, in any disclosed embodiment, the terms “substantially,” “approximately,” and “about” may be substituted with “within [a percentage] of” what is specified, where the percentage includes 0.1, 1, 5, and 10 percent.

### I. Separators and Microporous Membranes

Separators or microporous membranes (also referred to herein as a battery separator) are incorporated into batteries or cells to perform a variety of functions, for example to prevent electronic contact between positive and negative electrodes of a battery and enabling ionic transport between electrodes, acting as a thermal fuse as a shutdown feature, amongst others. Processes for making separators can be broadly divided into wet and dry processes. Wet processes generally involve mixing hydrocarbon liquid or another low molecular weight substance with a polyolefin resin, heating and melting the mixture, extruding the melt into a sheet, orienting the sheet in the machine direction (MD), transverse direction (TD), and/or biaxially, and then extracting the liquid with a solvent. Dry processes generally involve melting a polyolefin resin, extruding it into a film or sheet, thermally annealing the extruded film, and subsequently orienting the sheet, in for instance the MD, TD, and/or biaxially at increased or high temperatures to form micropores.

In some embodiments, a microporous film, membrane, separator, battery separator, elastic separator or substrate that can be incorporated into a battery or cell is described herein and can have one or more advantages over conventional membranes or separators, for example improved electrical resistance (ER) characteristics when under pressure and/or improved elasticity characteristics. In some embodiments, for example, ER characteristics of a microporous film or battery separator described herein can be enhanced by altering one or more structural properties including, but not limited to, film porosity, pore size, volume to accommodate electrolyte, resistance to blockage by electrochemical precipitates, and/or resistance to oxidation or reduction during use in a battery.

A separator or microporous membrane as described herein can comprise one or more layers of a polyolefin, a fluorocarbon, a polyamide, a polyester, a polyacetal (or a polyoxymethylene), a polysulfide, a polyvinyl alcohol, a polyvinylidene, co-polymers thereof, or combinations thereof.

In some embodiments, a separator or microporous membrane described herein comprises a polyolefin (PO) such as a polypropylene (PP) or a polyethylene (PE), a blend of polyolefins, one or more co-polymers of a polyolefin, or a combination of any of the foregoing.

It will be appreciated that a polyolefin as used in accordance with the present technology can be of any molecular weight not inconsistent with the characteristics of the microporous membranes or separators described herein.

In some embodiments, a polyolefin can be an ultra-low molecular weight, a low-molecular weight, a medium molecular weight, a high molecular weight, or an ultra-high molecular weight polyolefin, such as a medium or a high weight polyethylene (PE) or polypropylene (PP). For example, an ultra-high molecular weight polyolefin can have a molecular weight of 450,000 (450 k) or above, e.g. 500 k or above, 650 k or above, 700 k or above, 800 k or above, 1 million or above, 2 million or above, 3 million or above, 4 million or above, 5 million or above, 6 million or above, and so on. A high-molecular weight polyolefin can have a molecular weight in the range of 250 k to 450 k, such as 250 k to 400 k, 250 k to 350 k, or 250 k to 300 k. A medium molecular weight polyolefin can have a molecular weight from 150 to 250 k, such as 100 k, 125 k, 130K, 140 k, 150 k to 225 k, 150 k to 200 k, 150 k to 200 k, and so on. A low molecular weight polyolefin can have a molecular weight in the range of 100 k to 150 k, such as 100 k to 125 k. An ultra-low molecular weight polyolefin can have a molecular weight less than 100 k. The foregoing values are weight average molecular weights. In some embodiments, a higher molecular weight polyolefin can be used to increase strength or other properties of the porous membrane or batteries comprising the same as described herein. In some embodiments, a lower molecular weight polymer, such as a medium, low, or ultra-low molecular weight polymer can be beneficial. For example, without wishing to be bound by any particular theory, it is believed that the crystallization behavior of lower molecular weight polyolefins can result in a porous membrane having smaller pores resulting from at least an MD stretching process that forms the pores.

Fluorocarbons can comprise polytetrafluoroethylene (PTFE), polychlorotrifluoroethylene (PCTFE), fluorinated ethylene propylene (FEP), ethylenechlortrifluoroethylene (ECTFE), ethylene tetrafluoroethylene (ETFE), polyvinylidene fluoride (PVDF), polyvinylfluoride (PVF), prefluoroalkoxy (PFA) resin, co-polymers thereof, or combinations thereof. Polyamides can comprise, but are not limited to: polyamide 6, polyamide 6/6, Nylon 10/10, polyphthalamide (PPA), co-polymers thereof, or combinations thereof. Polyesters can comprise polyester terephthalate (PET), polybutylene terephthalate (PBT), poly-1-4-cyclohexylenedimethylene terephthalate (PCT), polyethylene naphthalate (PEN), or liquid crystal polymers (LCP). Polysulfides can comprise, but are not limited to, polyphenylsulfide, polyethylene sulfide, co-polymers thereof, or combinations thereof. Polyvinyl alcohols can comprise, but are not limited to, ethylenevinyl alcohol, co-polymers thereof, or combinations thereof. Polyvinylidenes include but are not limited to: fluorinated polyvinylidenes (such as polyvinylidonc chloride, polyvinylidene fluoride), copolymers thereof, and blends thereof.

A microporous membrane or separator can in some instances comprise a semi-crystalline polymer, such as polymers having a crystallinity in the range of 20 to 80%

In some embodiments, a microporous membrane or separator described herein can have a structure of a single layer, a bi-layer, a tri-layer, or multilayers. For example, a tri-layer or multilayer membrane can comprise two outer layers and one or more inner layers. In some instances, a microporous membrane can comprise 1, 2, 3, 4, 5, or more inner layers. In some other instances, each of the layers can be coextruded and/or laminated together.

Accordingly, a microporous membrane or separator can be made by a dry stretch process in which one or more polymers are extruded to form the membrane. Each of the outer and inner layers can be mono-extruded, where the layer is extruded by itself, without any sublayers (plies), or each layer can comprise a plurality of co-extruded sublayers. For example, each layer can comprise a plurality of sublayers, such as a co-extruded bi-sublayer, tri-sublayer, or multi-sublayer membrane, each of which can collectively considered to be a “layer”. The number of sublayers in coextruded bi-layer is two, the number of layers in a co-extruded tri-layer is three, and the number of layers in a co-extruded multi-layer membrane will be two or more, three or more, four or more, five or more, and so on. The exact number of sublayers in a co-extruded layer is dictated by the die design and not necessarily the materials that are co-extruded to form the co-extruded layer. For example, a co-extruded bi-, tri-, or multi-sublayer membrane can be formed using the same material in each of the two, three, or four or more sublayers, and these sublayers will still be considered to be separate sublayers even though each sublayer is made of the same material.

In some embodiments, a tri-layer or multilayer microporous membrane described herein can comprise two outer layers (such as a first outer layer and a second outer layer) and a single or plurality of inner layers. The plurality of inner layers can be mono-extruded or co-extruded layers. A lamination barrier can be formed between each of the inner layers and/or between each of the outer layers and one of the inner layers. A lamination barrier can be formed when two surfaces, such as two surfaces of different membranes or layers are laminated together using heat, pressure, or heat and pressure.

In some embodiments, a microporous membrane or separator as described herein can have any single layer, bi-layer, tri-layer, or multi-layer construction of PP and/or PE. In some embodiments, a microporous membrane described herein can have the following non-limiting constructions: PP, PE, PP/PP, PP/PE, PE/PP, PE/PE, PP/PP/PP, PP/PP/PE, PP/PE/PE. PP/PE/PP, PE/PP/PE, PE/PE/PP, PP/PP/PP/PP, PP/PE/PE/PP, PE/PP/PP/PE, PP/PE/PP/PP, PE/PE/PP/PP, PE/PP/PE/PP, PP/PE/PE/PE/PP, PE/PP/PP/PP/PE, PP/PP/PE/PP/PP, PE/PE/PP/PP/PE/PE, PP/PE/PP/PE/PP, PP/PP/PE/PE/PP/PP, PE/PE/PP/PP/PE/PE, PE/PP/PE/PP/PE/PP, PP/PE/PP/PE/PP/PE, PP/PP/PP/PE/PP/PP/PP, PE/PE/PE/PP/PE/PE/PE, PP/PE/PP/PE/PP/PE/PP, PE/PP/PE/PP/PE/PP/PE, PE/PP/PE/PP/PE/PP/PE/PP, PP/PE/PP/PE/PP/PE/PP/PE, PP/PP/PE/PE/PP/PP/PE/PE, PP/PE/PE/PE/PE/PE/PE/PP, PE/PP/PP/PP/PP/PP/PP/PE, PP/PP/PE/PE/PEPE/PP/PP, PP/PP/PP/PP/PE/PE/PE/PE, PP/PP/PP/PP/PE/PP/PP/PP/PP, PE/PE/PE/PE/PP/PE/PE/PE/PE, PP/PE/PP/PE/PP/PE/PP/PE/PP, PE/PP/PE/PP/PE/PP/PE/PP/PE, PE/PE/PE/PE/PE/PP/PP/PP/PP, PP/PP/PP/PP/PP/PE/PE/PE/PE, PP/PP/PP/PP/PP/PE/PE/PE/PE/PE, PE/PE/PE/PE/PE/PP/PP/PP/PP/PP, PP/PE/PP/PE/PP/PE/PP/PE/PP/PE, PE/PP/PE/PP/PE/PP/PE/PP/PE/PP, PE/PP/PP/PP/PP/PP/PP/PP/PP/PP/PE, PP/PE/PE/PE/PE/PE/PE/PE/PE/PE/PP, PP/PP/PE/PE/PP/PP/PE/PE/PP/PP, PE/PE/PP/PP/PP/PP/PP/PP/PP/PE/PE, PP/PP/PP/PE/PE/PP/PP/PP/PP/PE, or PE/PE/PE/PP/PP/PE/PE/PE/PP/PP. For purposes of reference herein PE denotes a single layer within the multilayer membrane that comprises PE. Similarly, PP denotes a single layer within the multilayer membrane that comprises PP. Thus, a PP/PE designation would represent a bi-layer membrane having a polypropylene (PP) layer and a polyethylene (PE) layer.

Individual layers in a separator or microporous membrane can comprise a plurality of sublayers, which can be formed by co-extrusion or combining the individual sublayers to form the individual layer of the multilayer membrane. Using a multilayer membrane having a structure of PP/PE/PP, each individual PP or PE layer can comprise two or more co-extruded sublayers. For example, when each individual PP or PE layer comprises three sublayers, each individual PP layer can be expressed as PP=(PP1,PP2,PP3) and each individual PE layer can be expressed as PE=(PE1,PE2,PE3). Thus, the structure of PP/PE/PP can be expressed as (PP1,PP2,PP3)/(PE1,PE2,PE3)/(PP1,PP2,PP3). The composition of each of the PP1, PP2, and PP3 sublayers can be the same, or each sublayer can have a different polypropylene composition than one or both of the other polypropylene sublayers. Similarly, composition of each of the PE1, PE2, and PE3 sublayers can be the same, or each sublayer can have a different polyethylene composition than one or both of the other polyethylene sublayers. This principle applies to other multilayer membranes having more or less layers that the above-described exemplary tri-layer membrane.

In some embodiments, a microporous membrane or separator described herein has an overall thickness of 1 micron to 60 microns, 1 micron to 55 microns, 1 micron to 50 microns, 1 micron to 45 microns, 1 micron to 40 microns, 1 micron to 35 microns, 1 micron to 30 microns, 1 micron to 25 microns, 1 micron to 20 microns, 1 micron to 15 microns, 1 micron to 10 microns, 5 microns to 50 microns, 5 microns to 40 microns, 5 microns to 30 microns, 5 microns to 25 microns, 5 microns to 20 microns, 5 microns to 10 microns, 10 microns to 40 microns, 10 microns to 35 microns, 10 microns to 30 microns, or 10 microns to 20 microns.

In some embodiments, each layer in bi-layer, tri-layer, or multi-layer microporous membrane or separator can have a thickness equal to a thickness of the other layers, or have a thickness that is less than or greater than a thickness of the other layers. For example, when a microporous membrane is a tri-layer membrane comprising a structure of PP/PE/PP or PE/PP/PE, the polypropylene layers can have a thickness equal to a thickness of the polyethylene layer(s), have a thickness less than a thickness of the polyethylene layer(s), or have a thickness greater than a thickness of the polyethylene layer(s).

In some embodiments, a microporous membrane described herein can be a tri-layer laminated PP/PE/PP (polypropylene/polyethylene/polypropylene) or a PE/PP/PE (polyethylene/polypropylene/polyethylene) microporous membrane. In some instances, a structure ratio of the layers of the microporous membrane can comprise 45/10/45%, 40/20/40%, 39/22/39%, 38/24/38%, 37/26/37%, 36/28/36%, 35/30/35%, 34.5/31/34.5%, 34/32/34%, 33.5/33/33.5%, 33/34/33%, 32.5/35/32.5%, 32/36/32%, 31.5/37/31.5%, 31/38/31%, 30.5/39/30.5%, 30/40/30%, 29.5/41/29.5%, 29/42/29%, 28.5/43/28.5%, 28/44/28%, 27.5/45/27.5%, or 27/46/27%.

A microporous membrane described herein can additionally comprise fillers, elastomers, wetting agents, lubricants, flame retardants, nucleating agents, and other additional elements not inconsistent with the objectives of this disclosure. For example, the membrane can comprise fillers such as calcium carbonate, zinc oxide, diatomaceous earth, talc, kaolin, synthetic silica, mica, clay, boron nitride, silicon dioxide, titanium dioxide, barium sulfate, aluminum hydroxide, magnesium hydroxide and the like, or combinations thereof. Elastomers can comprise ethylene-propylene (EPR), ethylene-propylene-diene (EPDM), styrene-butadiene (SBR), styrene isoprene (SIR), ethylidene norbornene (ENB), epoxy, and polyurethane or combinations thereof. Wetting agents can comprise ethoxylated alcohols, primary polymeric carboxylic acids, glycols (such as polypropylene glycol and polyethylene glycols), functionalized polyolefins, and the like. Lubricants can comprise a silicone, a fluoropolymer, oleamide, stearamide, erucamide, calcium stearate, or other metallic stearates. Flame retardants can comprise brominated flame retardants, ammonium phosphate, ammonium hydroxide, alumina trihydrate, and phosphate ester.

A microporous membrane or separator described in some of the embodiments herein, can in some instances, be made by a dry-stretch process. A microporous membrane is understood to be a thin, pliable, polymeric sheet, foil, or membrane having a plurality of pores extending therethrough. In some cases, the porous membrane is made by the dry-stretch process, which refers to a process where pore formation results from stretching a nonporous, semicrystalline, extruded polymer precursor in the machine direction (MD), transverse direction (TD), or in both an MD and TD (i.e. biaxially). Such a dry-stretch process is different from the wet process and the particle stretch process. Generally, in the wet process, also known as a phase inversion process, an extraction process, or a TIPS process, a polymeric raw material is mixed with a processing oil (sometimes referred to as a plasticizer), this mixture is extruded, and pores are formed when the processing oil is removed. While these wet process membranes may be stretched before or after the removal of the oil, the principle pore formation mechanism is the use of the processing oil.

A porous membrane can be a macroporous membrane, a mesoporous membrane, a microporous membrane, or a nanoporous membrane. The porosity of the membrane can be any porosity not inconsistent with the goals of this disclosure. For example, any porosity that could form an acceptable battery separator is acceptable. In some embodiments, the porosity of the porous substrate is from 20 to 90%, from 20 to 80%, from 40 to 80%, from 20 to 70%, from 40 to 70%, from 40-60%, more than 20%, more than 30%, or more than 40%. Porosity is measured using ASTM D-2873 and is defined as the percentage of void space, e.g., pores, in an area of the porous substrate, measured in the Machine Direction (MD) and the Transverse Direction (TD) of the substrate. In some embodiments, the pores are round with a sphericity factor of 0.25 to 8.0, or are oblong, or are oval-shaped.

A microporous membrane can have any Gurley not inconsistent with the objectives of this disclosure, such as a Gurly that is acceptable for use as a battery separator. Gurley is the Japanese Industrial Standard (JIS Gurley) and can be measured using a permeability tester, such as an OHKEN permeability tester. JIS Gurley is defined as the time in seconds required for 100 cc of air to pass through one square inch of membrane at a constant pressure of 4.9 inches of water. In some embodiments, the porous film or membrane described herein has a JIS Gurley (s/100 cc) of 150 or more, 160 or more, 170 or more, 180 or more, 190 or more, 200 or more, 210 or more, 220 or more, 230 or more, 240 or more, 250 or more, 260 or more, 270 or more, 280 or more, 290 or more, 300 or more, 310 or more, 320 or more, 330 or more, 340 or more, 350 or more, 100 to 800, 200 to 700, 200 to 600, 200 to 500, 200 to 400, 200 to 300, or 300 to 600.

A microporous membrane can have a puncture strength, uncoated, of 200 gf or more, 210 gf or more, 220 gf or more, 230 gf or more, 240 gf or more, 250 gf or more, 260 gf or more, 270 gf or more, 280 gf or more, 290 gf or more, 300 gf or more, 310 gf or more, 320 gf or more, 330 gf or more, 340 gf or more, 350 gf or more, or as high as 400 gf or more.

In some embodiments, a microporous membrane described herein can comprise one or more additives in at least one layer of the porous membrane. In some embodiments, at least one layer of a porous membrane comprises more than one, such as two, three, four, five, or more, additives. Additives can be present in one or both of the outermost layers of the porous membrane, in one or more inner layers, in all of the inner layers, or in all of the inner and both of the outermost layers. In some embodiments, additives can be present in one or more outermost layers and in one or more innermost layers. In such embodiments, over time, an additive can be released from the outermost layer or layers and the additive supply of the outermost layer or layers can be replenished by migration of the additive in the inner layers to the outermost layers. In some embodiments, each layer of a microporous membrane can comprise a different additive or combination of additives than an adjacent layer of the microporous membrane.

In some embodiments, an additive comprises a functionalized polymer. It will be appreciated that a functionalized polymer is a polymer with functional groups coming off of the polymeric backbone. In some embodiments, the functionalized polymer is a maleic anhydride functionalized polymer. In some further embodiments the maleic anhydride modified polymer is a maleic anhydride homo-polymer polypropylene, copolymer polypropylene, high density polypropylene, low-density polypropylene, ultra-high density polypropylene, ultra-low density polypropylene, homo-polymer polyethylene, copolymer polyethylene, high density polyethylene, low-density polyethylene, ultra-high density polyethylene, and/or ultra-low density polyethylene.

In some embodiments, an additive comprises an ionomer. An ionomer, as understood by one of ordinary skill in the art is a copolymer containing both ion-containing and non-ionic repeating groups. Sometimes the ion-containing repeating groups can make up less than 25%, less than 20%, or less than 15% of the ionomer. In some embodiments, the ionomer can be a Li-based, Na-based, or Zn-based ionomer. In some embodiments, an additive comprises cellulose nanofiber.

In some embodiments, an additive comprises inorganic particles having a narrow size distribution. For example, the difference between D10 and D90 in a distribution is less than 100 nanometers, less than 90 nanometers, less than 80 nanometers, less than 70 nanometers, less than 60 nanometers, less than 50 nanometers, less than 40 nanometers, less than 30 nanometers, less than 20 nanometers, or less than 10 nanometers. In some embodiments, the inorganic particles are selected from at least one of SiO₂, TiO₂, or combinations thereof.

In some embodiments, an additive comprises a lubricating agent. A lubricating agent or lubricant described herein can be any lubricating agent not inconsistent with the objectives of this disclosure. As understood by one of ordinary skill in the art, a lubricant is a compound that acts to reduce the frictional force between a variety of different surfaces, including the following: polymer:polymer; polymer:metal; polymer; organic material; and polymer:inorganic material. Specific examples of lubricating agents or lubricants as described herein are compounds comprising siloxy functional groups, including siloxanes and polysiloxanes, and fatty acid salts, including metal stearates.

Compounds comprising two or more, three or more, four or more, five or more, six or more, seven or more, eight or more, nine or more, or ten or more siloxy groups can be used as the lubricant described herein. Siloxanes, as understood by those in the art, are a class of molecules with a backbone of alternating silicon atom (Si) and oxygen (O) atoms, each silicon atom can have a connecting hydrogen (H) or a saturated or unsaturated organic group, such as —CH3 or C2H5. Polysiloxanes are a polymerized siloxanes, usually having a higher molecular weight. In some embodiments described herein, the polysiloxanes can be high molecular weight, such as ultra-high molecular weight polysiloxanes. In some embodiments, high and ultra-high molecular weight polysiloxanes can have weight average molecular weights ranging from 500,000 to 1,000,000.

A fatty acid salt described herein can be any fatty acid salt not inconsistent with the objectives of this disclosure. In some instances, a fatty acid salt can be any fatty acid salt that acts as a lubricant. The fatty acid of the fatty acid salt can be a fatty acid having between 12 to 22 carbon atoms. For example, the metal fatty acid can be selected from the group consisting of: Lauric acid, myristic acid, palmitic acid, stearic acid, oleic acid, linoleic acid, linolenic acid, palmitoleic acid, behenic acid, crucic acid, and arachidic acid. The metal can be any metal not inconsistent with the objectives of this disclosure. In some instances, the metal is an alkaline or alkaline earth metal, such as Li, Be, Na, Mg, K, Ca, Rb, Sr, Cs, Ba, Fr, and Ra. In some embodiments, the metal is Li, Be, Na, Mg, K, or Ca. In some instances a fatty acid salt can be lithium stearate, sodium stearate, lithium oleate, sodium oleate, sodium palmitate, lithium palmitate, potassium stearate, or potassium oleate.

A lubricant, including the fatty acid salts described herein, can have a melting point of 200° C. or above, 210° C. or above, 220° C. or above, 230° C. or above, or 240° C. or above. A fatty acid salt such as lithium stearate (melting point of 220° C.) or sodium stearate (melting point 245 to 255° C.) has such a melting point.

In some embodiments, an additive can comprise one or more nucleating agents. As understood by one of ordinary skill in the art, nucleating agents are, in some embodiments, materials, inorganic materials, that assist in, increase, or enhance crystallization of polymers, including semi-crystalline polymers.

In some embodiments, an additive can comprise a cavitation promoter. Cavitation promoters, as understood by those skilled in the art, are materials that form, assist in formation of, increase formation of, or enhance the formation of bubbles or voids in the polymer. In some embodiments, an additive can comprise a fluoropolymer, such as the fluoropolymers discussed in detail herein. In some embodiments, an additive can comprise a cross-linker.

In some embodiments, an additive can comprise an x-ray detectable material. An x-ray detectable material can be any x-ray detectable material not inconsistent with the objectives of this disclosure. Suitable amounts of the x-ray detectable material or element include, for example, up to 50 weight %, up to 40 weight %, up to 30 weight %, up to 20 weight %, up to 10 weight %, up to 5 weight %, or up to 1 weight % based on the total weight of the porous film or membrane can be used. In an embodiment, the additive is barium sulfate.

In some embodiments, an additive can comprise a lithium halide. The lithium halide can be lithium chloride, lithium fluoride, lithium bromide, or lithium iodide. The lithium halide can be lithium iodide, which is both ionically conductive and electrically insulative. In some instances, a material that is both ionically conductive and electrically insulative can be used as part of a battery separator.

In some embodiments, an additive can comprise a polymer processing agent. As understood by those skilled in the art, polymer processing agents or additives are added to improve processing efficiency and quality of polymeric compounds. In some embodiments, the polymer processing agent can be antioxidants, stabilizers, lubricants, processing aids, nucleating agents, colorants, antistatic agents, plasticizers, or fillers.

In some embodiments, an additive can comprise high temperature melt index (HTMI) polymer. The HTMI polymer can be any HTMI polymer not inconsistent with the objectives of this disclosure. In some instances, the HTMI polymer can be at least one selected from the group consisting of PMP, PMMA, PET, PVDF, Aramid, syndiotactic polystyrene, and combinations thereof.

In some embodiments, an additive can comprise an electrolyte. Electrolytes as described herein can be any electrolyte not inconsistent with the objectives of this disclosure. The electrolyte can be any additive typically added by battery makers, particularly lithium battery makers to improve battery performance. Electrolytes must also be capable of being combined, such as miscible, with the polymers used for the polymeric porous membrane or compatible with the coating slurry. Miscibility of the additives can also be assisted or improved by coating or partially coating the additives. In some embodiments, the electrolyte is at least one selected from the group consisting of a solid electrolyte interphase (SEI) improving agent, a cathode protection agent, a flame retardant additive, LiPF₆ salt stabilizer, an overcharge protector, an aluminum corrosion inhibitor, a lithium deposition agent or improver, or a solvation enhancer, an aluminum corrosion inhibitor, a wetting agent, and a viscosity improver. In some embodiments, the electrolyte can have more than one property, such as it can be a wetting agent and a viscosity improver.

Exemple SEI improving agents include VEC (vinyl ethylene carbonate), VC (vinylenc carbonate), FEC (fluoroethylene carbonate), LiBOB (Lithium bis (oxalato) borate). Exemplary cathode protection agents include N,N′-dicyclohexylcarbodiimide, N,N-diethylamino trimethylsilane, LiBOB. Exemplary flame-retardant additives include TTFP (tris (2,2,2-trifluorocthyl) phosphate), fluorinated propylene carbonates, MFE (methyl nonafluorobuyl ether). Exemplary LiPF₆ salt stabilizers include LIF,TTFP (tris (2,2,2-trifluoroethyl) phosphite), 1-methyl-2-pyrrolidinone, fluorinated carbamate, hexamethyl-phosphoramide. Exemplary overcharge protectors include xylene, cyclohexylbenzene, biphenyl, 2, 2-diphenylpropane, phenyl-tert-butyl carbonate. Exemplary Li deposition improvers include AII₃, Snl₂, cetyltrimethylammonium chlorides, perfluoropolyethers, tetraalkylammonium chlorides with a long alkyl chain. Exemplary ionic salvation enhancer include 12-crown-4, TPFPB (tris (pentafluorophenyl)). Exemplary Al corrosion inhibitors include LiBOB, LiODFB, such as borate salts. Exemplary wetting agents and viscosity dilutersinclude cyclohexane and P₂O₅.

In some embodiments, the electrolyte additive is air stable or resistant to oxidation. A battery separator comprising the electrolyte additive disclosed herein can have a shelf life of weeks to months, e.g. one week to 11 months. In some embodiments, an additive can comprise an energy dissipative non-miscible additive. Non-miscible means that the additive is not miscible with the polymer used to form the layer of the porous film or membrane that contains the additive.

A membrane described herein can be MD stretched or TD stretched to make the membrane porous. In some instances, the microporous membrane is produced by sequentially performing a TD stretch of an MD stretched microporous membrane, or by sequentially performing an MD stretch of a TD stretched microporous membrane. In addition to a sequential MD-TD stretching, the microporous membrane can also simultaneously undergo a biaxial MD-TD stretching. Moreover, the simultaneous or sequential MD-TD stretched porous membrane can be followed by a subsequent calendering step to reduce the membrane's thickness, reduce roughness, reduce percent porosity, increase TD tensile strength, increase uniformity, and/or reduce TD splittiness.

In some embodiments, a microporous membrane can comprise pores having an average pore size of 0.01 micron to 1 micron, 0.02 micron to 1 micron, 0.03 micron to 1 micron, 0.04 micron to 1 micron, 0.05 micron to 1 micron, 0.06 micron to 1 micron, 0.07 micron to 1 micron, 0.08 micron to 1 micron, 0.09 micron to 1 micron, 0.1 micron to 1 micron, 0.2 micron to 1 micron, 0.3 micron to 1 micron, 0.4 micron to 1 micron, 0.5 micron to 1 micron, 0.6 micron to 1 micron, 0.7 micron to 1 micron, 0.8 micron to 1 micron, 0.9 micron to 1 micron, 0.01 micron to 0.9 micron, 0.01 micron to 0.8 micron, 0.01 micron to 0.7 micron, 0.01 micron to 0.6 micron, 0.01 micron to 0.5 micron, 0.01 micron to 0.4 micron, 0.01 micron to 0.3 micron, 0.01 micron to 0.2 micron, 0.01 micron to 0.1 micron, 0.01 micron to 0.09 micron, 0.01 micron to 0.08 micron, 0.01 micron to 0.07 micron, 0.01 micron to 0.06 micron, 0.01 micron to 0.05 micron, 0.01 micron to 0.04 micron, 0.01 micron to 0.03 micron, 1 micron, 0.9 micron, 0.8 micron, 0.7 micron, 0.6 micron, 0.5 micron, 0.4 micron, 0.3 micron, 0.2 micron, 0.1 micron, 0.09 micron, 0.08 micron, 0.07 micron, 0.06 micron, 0.05 micron, 0.04 micron, 0.03 micron, 0.02 micron, or 0.01 micron.

In an embodiment, a porous membrane can be manufactured using an exemplary process that includes stretching and a subsequent calendering step such as a machine direction stretching followed by transverse direction stretching (with or without machine direction relax) and a subsequent calendering step as a method of reducing the thickness of such a stretched membrane, for example, a multilayer porous membrane, in a controlled manner, to reduce the percent porosity of such a stretched membrane, for example, a multilayer porous membrane, in a controlled manner, and/or to improve the strength, properties, and/or performance of such a stretched membrane, for example, a multilayer porous membrane, in a controlled manner, such as the puncture strength, machine direction and/or transverse direction tensile strength, uniformity, wettability, coatability, runnability, compression, spring back, tortuosity, permeability, thickness, pin removal force, mechanical strength, surface roughness, hot tip hole propagation, and/or combinations thereof, of such a stretched membrane, for example, a multilayer porous membrane, in a controlled manner, and/or to produce a unique structure, pore structure, material, membrane, base membrane, and/or separator.

In some instances, the TD tensile strength of the multilayer membrane can be further improved by the addition of a calendering step following TD stretching. The calendering process typically involves heat and pressure that can reduce the thickness of a porous membrane. The calendering process step can recover the loss of MD and TD tensile strength caused by TD stretching. Furthermore, the increase observed in MD and TD tensile strength with calendering can create a more balanced ratio of MD and TD tensile strength which can be beneficial to the overall mechanical performance of the multilayer membrane.

The calendering process can use uniform or non-uniform heat, pressure and/or speed to selectively densify a heat sensitive material, to provide a uniform or non-uniform calender condition (such as by use of a smooth roll, rough roll, patterned roll, micro pattern roll, nano pattern roll, speed change, temperature change, pressure change, humidity change, double roll step, multiple roll step, or combinations thereof), to produce improved, desired or unique structures, characteristics, and/or performance, to produce or control the resultant structures, characteristics, and/or performance, and/or the like. In an embodiment, a calendering temperature of 50° C. to 70° C. and a line speed of 40 to 80 ft/min can be used, with a calendering pressure of 50 to 200 psi. The higher pressure can in some instances provide a thinner separator, and the lower pressure provide a thicker separator.

In some embodiments, one or more coating layers can be applied to one or two sides of the multilayer membrane. In some embodiments, one or more of the coatings can be a ceramic coating comprising a polymeric binder and organic and/or inorganic particles. In some embodiments, only a ceramic coating is applied to one or both sides of the microporous membrane. In other embodiments, a different coating can be applied to the microporous membrane before or after the application of the ceramic coating. The different additional coating can be applied to one or both sides of the membrane or film also. In some embodiments, the different polymeric coating layer can comprise at least one of polyvinylidene difluoride (PVdF) or polycarbonate (PC).

In some embodiments, the thickness of the coating layer is less than about 12 μm, sometimes less than 10 μm, sometimes less than 9 μm, sometimes less than 8 μm, sometimes less than 7 μm, and sometimes less than 5 μm. In at least certain selected embodiments, the coating layer is less than 4 μm, less than 2 μm, or less than 1 μm.

The coating method is not so limited, and the coating layer described herein can be coated onto a porous substrate by at least one of the following coating methods: extrusion coating, roll coating, gravure coating, printing, knife coating, air-knife coating, spray coating, dip coating, or curtain coating. The coating process can be conducted at room temperature or at elevated temperatures.

The coating layer can be any one of nonporous, nanoporous, microporous, mesoporous or macroporous. The coating layer can have a JIS Gurley of 700 or less, sometimes 600 or less, 500 or less, 400 or less, 300 or less, 200 or less, or 100 or less.

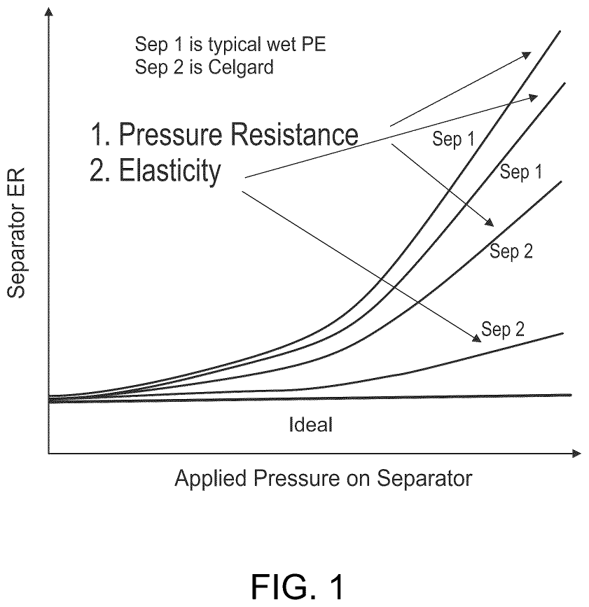

In some embodiments, a microporous membrane or separator can have an electrical resistance (ER) of less than or equal to 10 Ω/mm, less than or equal to 7 Ω/mm, or less than or equal to 5 Ω/mm when subjected to a compression pressure of 1,000 lbs., where the ER is normalized for compression thickness. In some further embodiments, a microporous membrane or separator can have an ER of less than or equal to 25 Ω/mm, less than or equal to 20 Ω/mm, or less than or equal to 15 Ω/mm when subjected to a compression pressure of 5,000 lbs., where the ER is normalized for compression thickness. In some further embodiments, a microporous membrane or separator can have an ER of less than or equal to 37 Ω/mm, less than or equal to 35 Ω/mm, less than or equal to 30 Ω/mm, or less than or equal to 25 Ω/mm when subjected to a compression pressure of 7,500 lbs., where the ER is normalized for compression thickness. In some even further embodiments, a microporous membrane or separator can have an ER of less than or equal to 47 Ω/mm, less than or equal to 45 Ω/mm, less than or equal to 40 Ω/mm, less than or equal to 35 Ω/mm, or less than or equal to 30 Ω/mm when subjected to a compression pressure of 10,000 lbs., where the ER is normalized for compression thickness. Referring briefly to FIG. 1, FIG. 1 illustrates the ER and elasticity characteristics of a separator or microporous membrane according to some embodiments of the present technology as compared to a typical or conventional separator. As can be seen, separators or microporous membranes according to the present technology (Celgard/September 2) have better elasticity properties as applied pressure on a separator or microporous membrane increases, and furthermore, maintains a substantially lower ER as applied pressure on the separator or microporous membrane increases with lower ER increases (i.e. separator ER slope is more gradual as applied pressure increases). Separator 2, for example, approached the ideal separator behavior regarding minimal to no increases in ER with increased applied pressure.

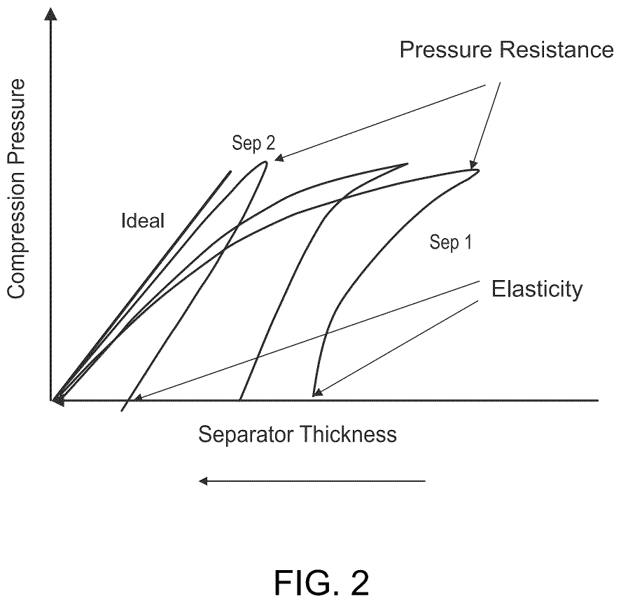

In some embodiments a microporous membrane or separator can exhibit good elasticity characteristics. Accordingly, in some embodiments a microporous membrane or separator can exhibit a compression from about 5% to about 10%, or more particularly from about 6% to about 10% under a stress of 8 N/mm². In some other embodiments, a microporous membrane or separator can exhibit a recovery from about 50% to about 100%, from about 60% to about 100%, from about 70% to about 100%, from about 80% to about 100%, from about 90% to about 100%, or from about 95% to about 100% after an applied pressure is removed from the microporous membrane or separator. Referring briefly to FIG. 2, FIG. 2 illustrates the pressure resistance and separator elasticity properties, according to the technology described herein. As is shown, a separator or microporous membrane as described herein exhibits better pressure resistance and better elasticity and/or recovery than a comparable conventional membrane as compression pressure on a separator or microporous membrane is increased.

### II. Batteries or Cells

In some embodiments, a microporous membrane or separator as described herein can be incorporated into a battery or cell. The microporous membrane or separator can have any composition and/or properties described in Section I hereinabove. A battery or cell can include, amongst other components, an anode, a cathode, and a separator disposed between the anode and cathode. In some embodiments, a battery or cell can be a cylindrical cell. In some embodiments, an electrode (i.e. an anode and/or cathode) can expand by at least 1%, by at least 3%, by at least 5%, by at least 7%, or by at least 10% during use. In some further embodiments, an anode can exhibit an increase in volume greater than 1%, greater than 3%, greater than 5%, or greater than 7% during charge.

The cathode, according to some embodiments of the present technology, can have a smooth and/or rounded cathode edge, and/or furthermore have a polymer-coated cathode edge.

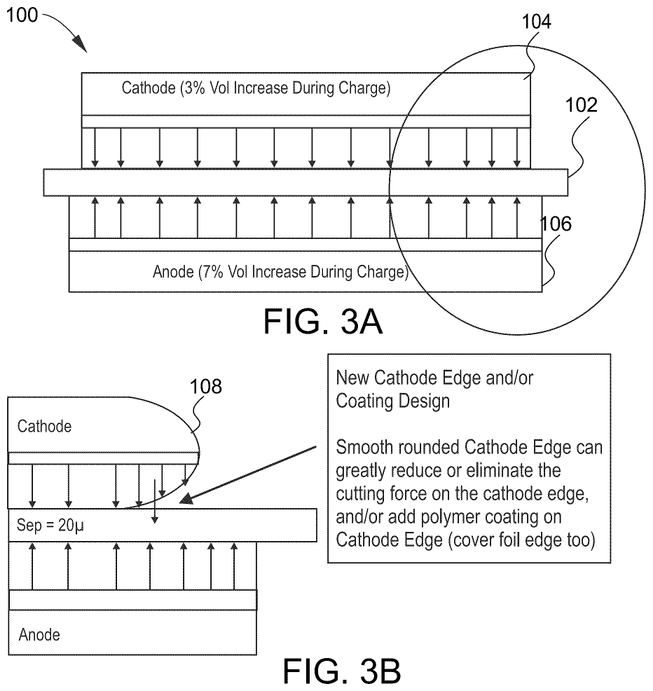

Referring now to FIG. 3A, FIG. 3A depicts a diagram of an example battery or cell structure 100 illustrating componants thereof, according to embodiments of the present technology. It should be understood that this and other arrangements described herein are set forth as only examples. Other arrangements and elements can be used in addition to, or instead of, those shown, and some elements can be omitted altogether for the sake of clarity. Among components shown, the battery structure 100 includes a membrane or separator 102 (e.g. a microporous membrane), an anode or positive electrode 104 and a cathode or negative electrode 106. As indicated, in operation or during charge, the anode 104 and the cathode 106 can undergo a volume increase, thereby applying pressure on the separator or membrane. As discussed herein, the separator 102 can exhibit good electrical resistance, pressure resistance, and elasticity. Turning to FIG. 3B, FIG. 3B depicts a magnified view of a portion of 3A. Accordingly, as can be seen, cathode 106 is formed such that it comprises a rounded edge portion 108. The smooth, rounded edge portion 108 can in some instances reduce or eliminate the cutting force of the cathode 106 edge as the cathode 106 expands and applies pressure to the separator or membrane 102. In some instances, the rounded edge portion 108 as incorporated into the cathode 106 can reduce or eliminate TD and/or MD splitting in the separator or membrane 102. In some embodiments, the cathode 106 may be coated, or in some other embodiments a portion of the cathode may be coated, for example the portion of the cathode 106 corresponding to the rounded edge portion 108.

III. Battery, Cell and/or Component Testing

According to some embodiments of the technology described herein, improved battery or cell and/or separator testing and related apparatus are provided, for example internal short resistance (ISR) testing. As will be appreciated, current battery or cell testing, and more particularly separator testing, are generally taken from the textile industry and therefore may not generally take into consideration battery or cell needs and/or requirements. Therefore, the present technology, at least in part, provides testing methods and apparatus that takes into consideration separator impact on battery or cell safety and/or performance.

Accordingly, some embodiments are directed towards an ISR test to measure the force required to create a short through a separator due to internal short resistance (i.e. electrode short). In some aspects, an ISR test measures the strength of a given separator (e.g. microporous membrane) for use in a battery or cell and its resistance towards electrode penetration. Testing in accordance with the present technology, can be more closely aligned to simulating behavior of a battery or cell, and more closely relates to particle penetration resistance as compared to puncture resistance. Further, ISR strength may be used to indicate a tendency of a separator to allow short-circuits battery or cell operation, performance, and/or testing.

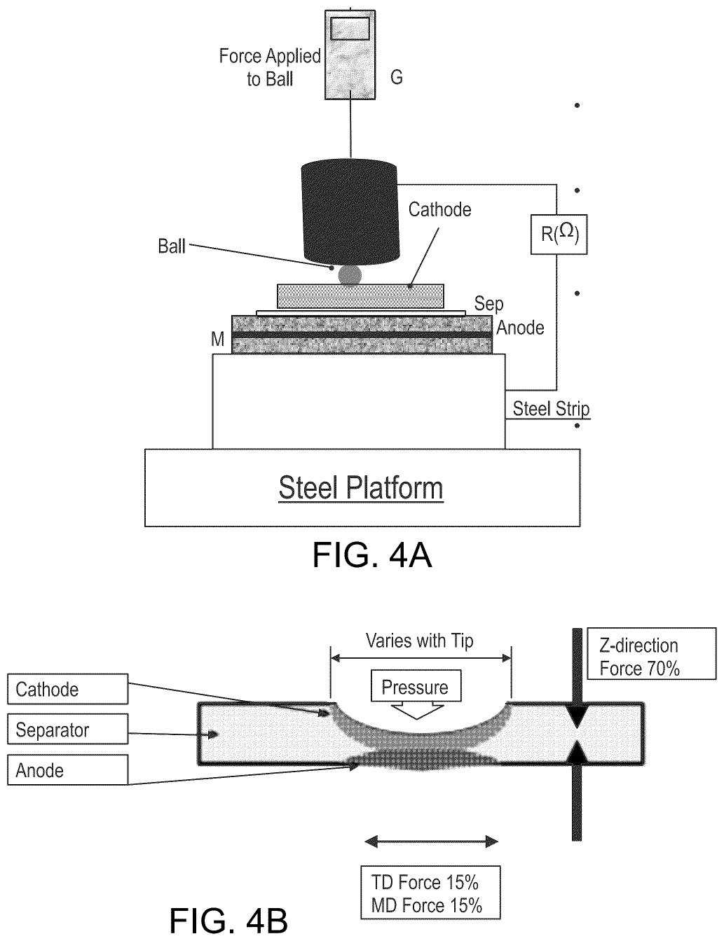

Referring to FIG. 4A, FIG. 4A illustrates an internal short resistance (ISR) test and related apparatus, in accordance with embodiments of the present technology. An ISR test can in some instances test the force required to create a short through a separator due to internal short resistance (i.e. an electrode short). Additionally, an ISR test can measure the strength of a given separator, and its resistance towards electrode penetration. ISR test 400 includes, among components not shown, applying a force 410 to a ball 412 that is in mechanical and/or electrical communication with a test stack 414. Test stack 414 comprises cathode 416, separator 418, anode 420, steel strip 422, and steel platform 424. In some instances, the ball 412 is harder than the steel strip, and accordingly in some instances steel strip 422 can be deformed during testing. In some example embodiments, the ball 412 can have a diameter from about 0.01 inches to about 10 inches in diameter. In some other embodiments, the ball 412 can have a diameter from about 0.25 inches to about 5 inches in diameter. In some other embodiments, the ball 412 can have a diameter from about 0.50 inches to about 3 inches in diameter. As each force 410 is applied (e.g. incremental applications of force) a resistance can be measured and/or otherwise calculated, and one or more layers of test stack 414 is deformed based on a force applied to ball 412. In some instances, each time a force 410 is applied a discrete measurement may be taken, and further, deformation of a layer in test stack 414 can be measured. In some instances, for each discrete test, the platform 424 can be indexed to a new location as the test stack 414 is deformed under the ball 412 via the applied pressure (e.g. applied pressure 410).

Turning to FIG. 4B a short circuit through a separator is illustrated, where internal short resistance is primarily provided in the Z-direction. As such measurements in the z-direction are taken with respect to the force applied. Additionally, internal short resistance may also be provided in the TD or MD of a given separator. It will be appreciated that resistance, or further, for instance ISR, are related to mechanical characteristics of a separator and/or battery, such as a resistance or strength in the Z-direction of a separator. According to embodiments described herein, an improved ISR test is provided, for example in accordance with FIG. 4C. At step 450, a force component(s), a ball, and a test stack (e.g. test stack 414 of FIG. 4A) are provided. The ball can be in mechanical and/or electrical communication with the test stack. In some embodiments the ball is physically connected to one of the force components. In some further embodiments the ball is the force component, and further sometimes referred to as a pin. At step 460 the force component(s) and ball engage the test stack and apply a pressure or force to the test stack, essentially squeezing the anode, cathode, and separator. Force may be applied incrementally or increased as a function of time. At step 470, enough force is applied by the ball or pin and the separator is punctured thereby generating a short circuit between the anode and cathode, and a measurement of internal short resistance is calculated and/or generated (e.g. in kgf). At step 480, the platform of the test stack is indexed to a new location as the test stack is deformed to begin a subsequent test cycle.

In further embodiments according to the technology described herein, improved wetting tests, mechanisms, and/or equipment/apparatus are provided. As illustrated in FGS. 6A and 6B, a wetting testing apparatus, methodology, and/or test are illustrated. As will be appreciated apparatus and methods described herein provide a truer test of wetting of a separator as compared to conventional means. As illustrated, a device can include a chamber (e.g. PTFE or HD PE) having a lid with an electrolyte injection port and a sealing ring (e.g. PTFE ring). In the chamber can be two copper (or other conductive material) blocks biased toward one another by a spring mechanism. In one test scenario, a separator stack is placed between the blocks, wherein the separator stack comprises the configuration: anode/separator/anode/separator/anode. It will be appreciated that any combination stack of anode, cathode, and separator may be used.

A vacuum pump is attached to a T valve at the top of the electrolyte injection port. A vacuum is drawn on the closed chamber. The T valve is turned and electrolyte in a syringe device attached to the top of the T valve releases electrolyte into the chamber to wet out the separator stack.

An impedance or LCR device is electrically connected to the copper blocks by the one or more wires (i.e. driving force). Another wire (e.g. black wire) is a probe. First, the Impedance or LCR device is used to sweep for the frequency (for example 3 Kh or 7 Kh). Second, after the Frequency is found, the Frequency is set and voltage is set (for example 5 mV AC) and the impedance or LCR device is used to determine the Impedance or R over time (and the RCT).

Before Electrolyte enters the R is infinite. Over time (t), the R drops and almost reaches stability (or constant R). The R decay over time (RCT) slope is related to the true wetting behavior of the anode separator stack. The First term t1 relates to the wetting behavior. For example, 2×t1 may be 67% wet out, and 3×t1 may be 90% wet out.

The anode separator stack is removed and a similar second experiment or test phase (find frequency, test R over time) is run for the cathode separator stack: Cathode/Separator/Cathode/Separator/Cathode. The anode t1 and cathode t1 are usually very similar but if not, then their respective t1 can show the slow to wet electrode (or electrode plus separator system). It will be appreciated that this test equipment, methodology and test is a more true test of actual anode, cathode, separator, and battery or cell electrolyte wetting than prior tests. The separator is between electrodes, under pressure, and wet with electrolyte.

Embodiments described herein can be understood more readily by reference to the following Examples. Elements, apparatus, and methods described herein, however, are not limited to any specific embodiment presented in the Examples. It should be recognized that these are merely illustrative of some principles of this disclosure, and are non-limiting. Numerous modifications and adaptations will be readily apparent without departing from the spirit and scope of the disclosure.

### Examples(s)

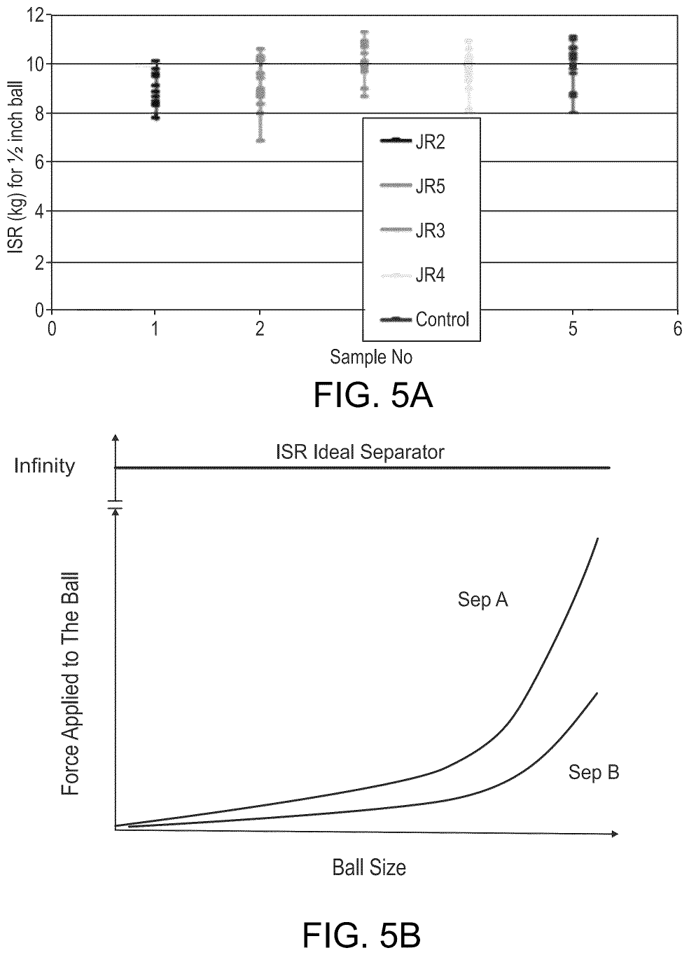

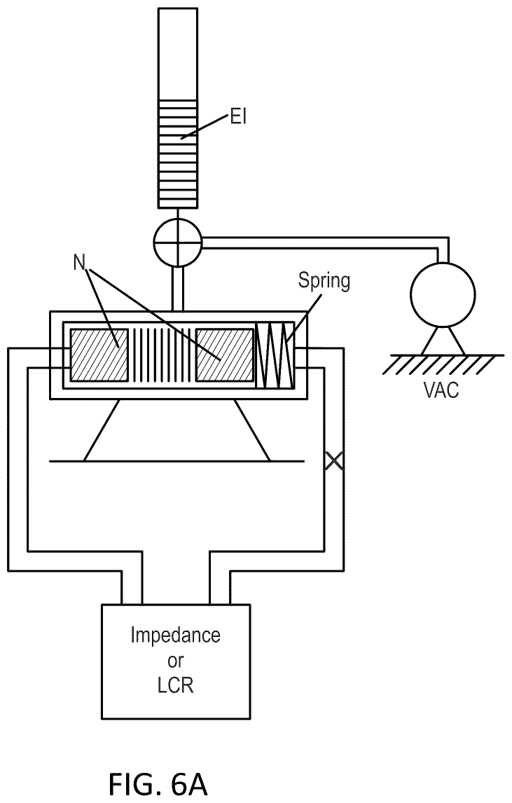

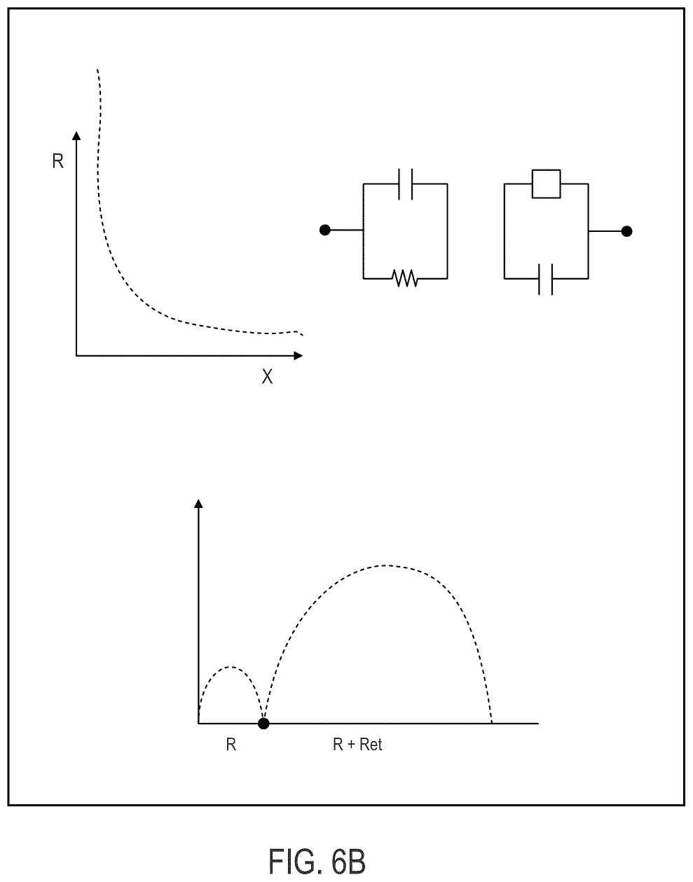

Membranes, or separators, in accordance with aspects of the technology described in Section I herein were prepared and tested by an ISR test method in accordance with embodiments of the technology described herein. Referring to FIGS. 5A and 5B, internal short resistance data are provided for samples 2-5 depicted and a control for a test performed with a ball having a diameter of 0.5 inches. With respect to FIG. 5B, FIG. 5B illustrates the measured ISR for a separator A and a separator B as a function of ball size used in an ISR test. As shown in FIG. 5B, Separator A has a better ISR than Separator B.

Membranes, or separators, in accordance with aspects of the technology described in Section I herein were prepared according to Table 1. The example separators were subsequently tested and illustrate improved properties, for example good compression/recovery properties, and electronic resistance under varying degrees of pressure.

TABLE 1

| Sample | Structure |
|---|---|
| 1 | 16 μm dry co-extruded PP |
| 2 | 16 μm dry trilayer PP/PE/PP |
| 3 | 10 μm dry trilayer PE/PP/PP |
| 4 | 10 μm dry PE |
| 5 | 10 μm dry PE/PP/PP, w/elastomer in a layer |
| 6 | Dry PO + CCS |

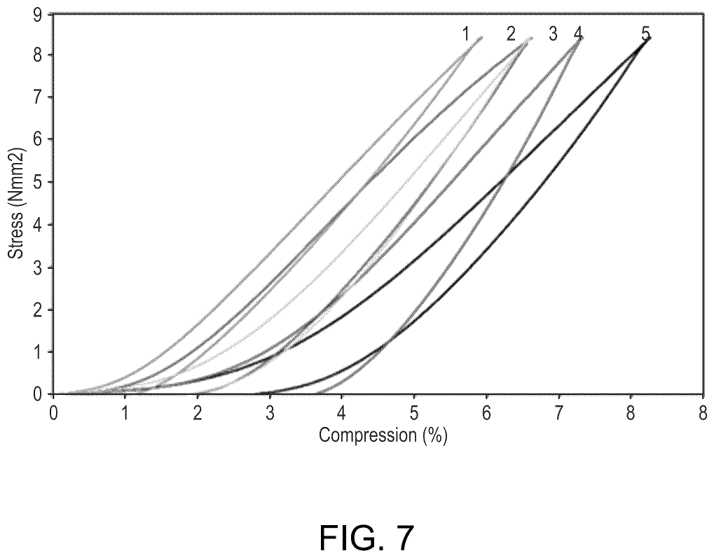

In one testing set, samples 1-5 were tested according to a dry film test with respect to compression and elasticity characteristics. First, the initial thickness of a stack of dry membranes is measured (i.e. none of the membranes in a stack is wet with electrolyte), for example a thickness of about 5 mm was used for the instant examples. A single or double column universal testing system was implemented to perform one or more mechanical tests on the sample separators, for instance tensile, compression, flexure/bend, peel, tear, and shear tests. For some of the compression tests, the universal testing system was coupled to a compression platen, for instance a 46 mm compression platen. A quartz disc, for example a TMA quartz disc, is also implemented as a test foot area to elevate stress on one or more of the samples. An initial pressure is applied, for instance an initial pressure of 8 psi is applied for an accurate initial thickness, and the pressure on the sample or sample stack is increased from 8 psi to a final pressure, for example 1232 psi, the pressure is released, and subsequently the stress-strain curve for the sample or sample stack is recorded. Referring to FIG. 7, FIG. 7 illustrates the stress-strain curves for samples 1-5 having corresponding structures as described in Table 1. As shown in FIG. 7, the separators tested were found to have varying degrees of compressibility and elasticity. It will be appreciated that separators (or membranes) that are compressible and elastic are desirable. Sample 1, for example, exhibits a compression of greater than 5% and nearly a 100% recovery after pressure on the sample is released. Good compression and elasticity characteristics of a separator, such as those described herein, are useful in batteries that include electrodes that swell and contract. For instance, during battery operation a separator may be configured to handle, or conform, to pressure exerted on it by a swelling electrode, and subsequently return to its originally thickness as the pressure subsides. Accordingly, good compression and/or elasticity properties of a separator impart pressure handling capabilities to a battery or cell. Otherwise, with poor compression and/or elasticity properties, after being compressed due to swelling of electrodes the separator does not return to its original thickness or near its original thickness, a gap may be left between the separator and the electrodes. Such gaps provide areas for dendrites to grow, which can lead to short circuits in the battery or cell and potentially explosions and other safety issues.

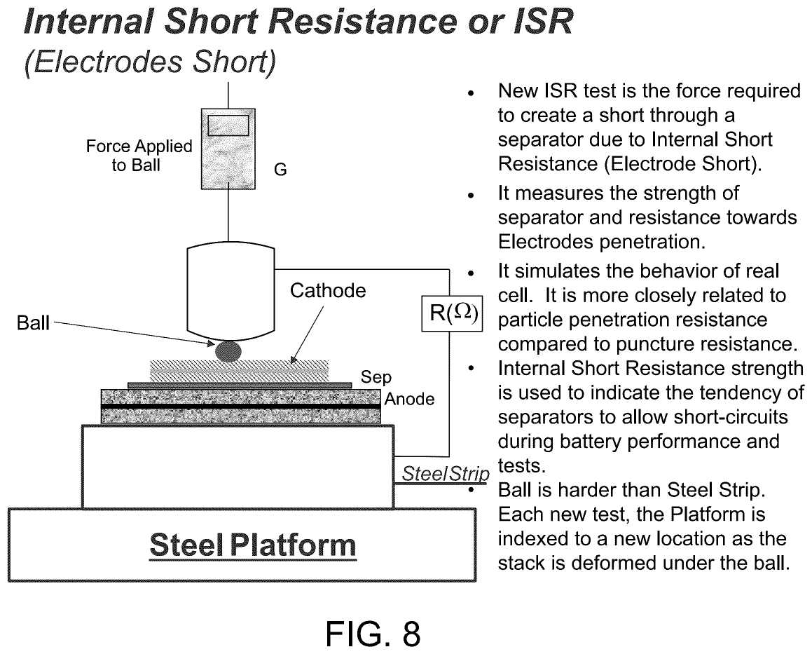

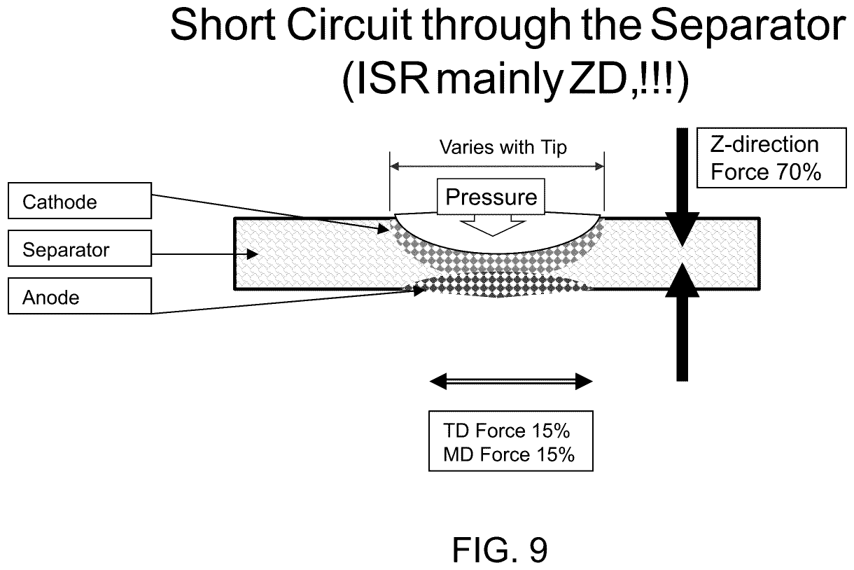

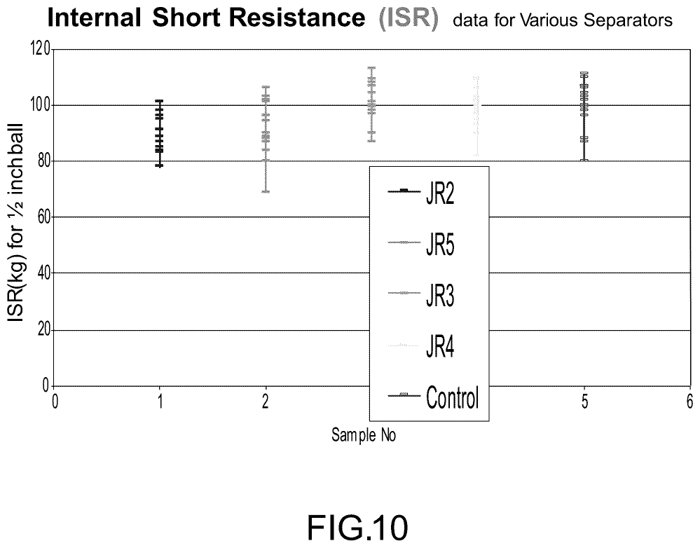

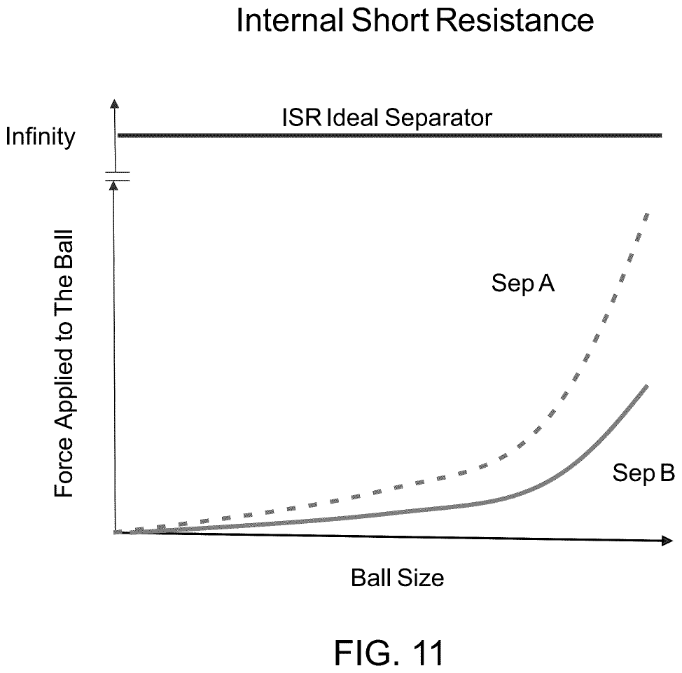

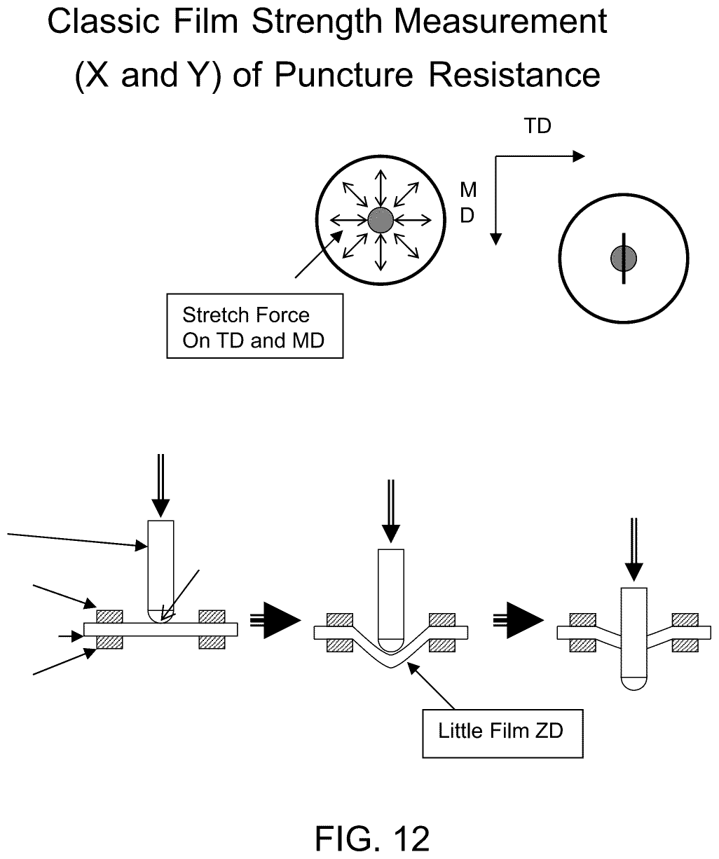

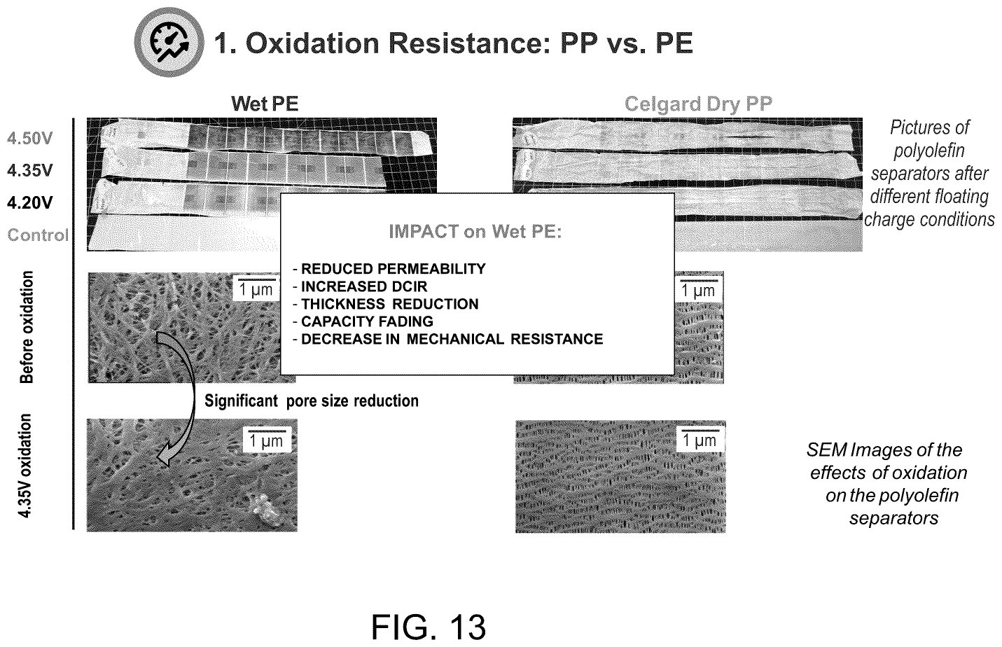

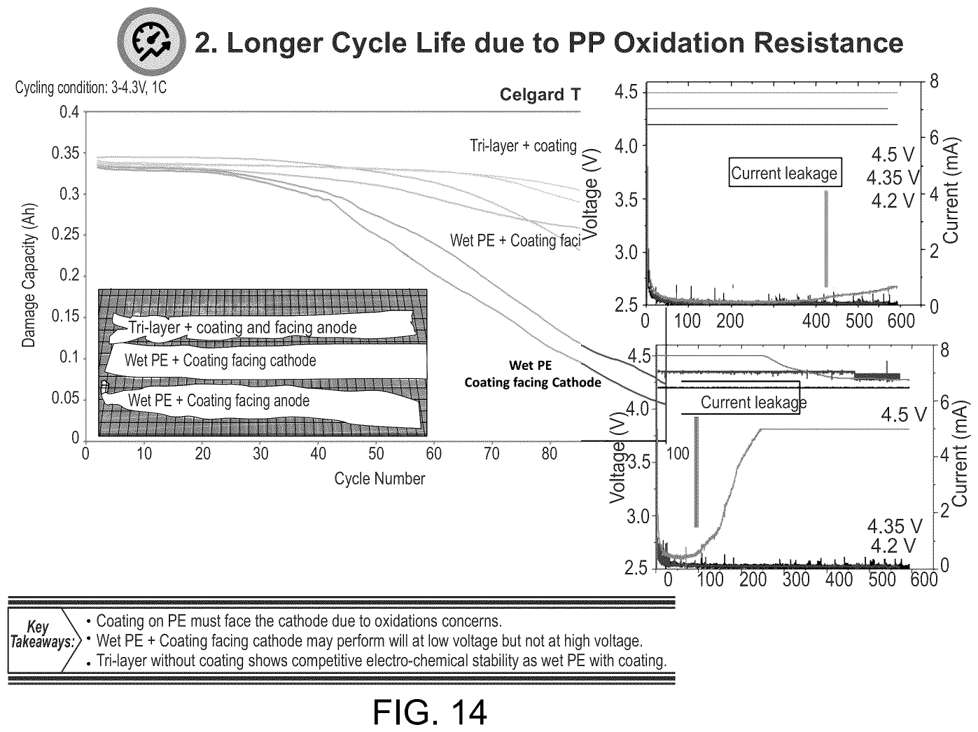

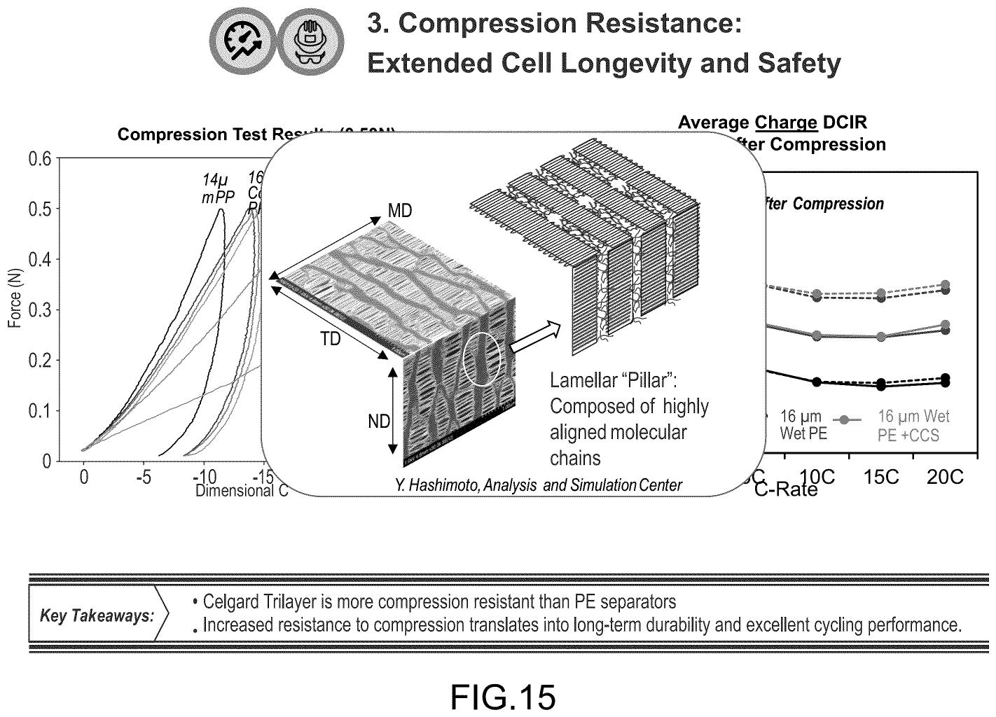

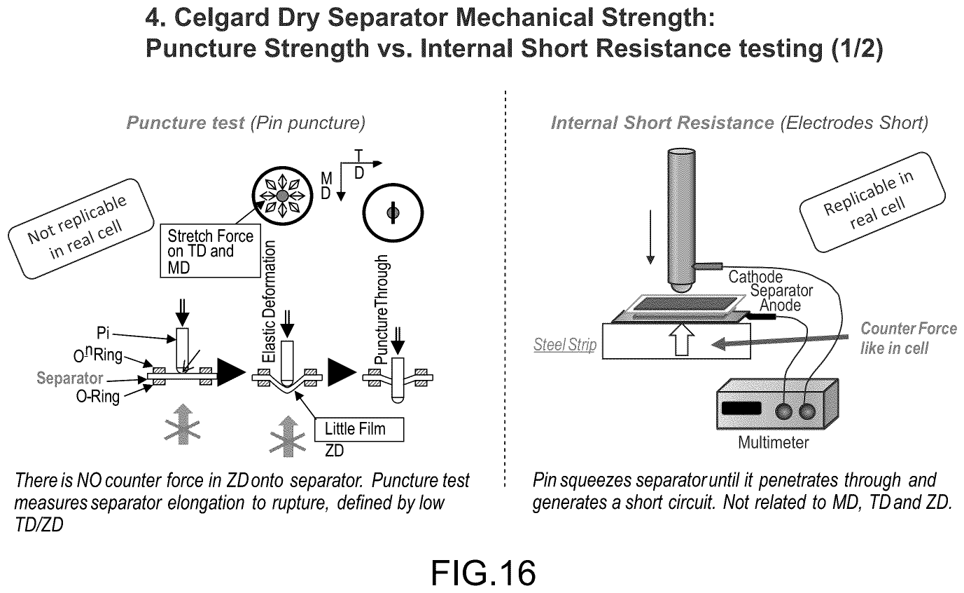

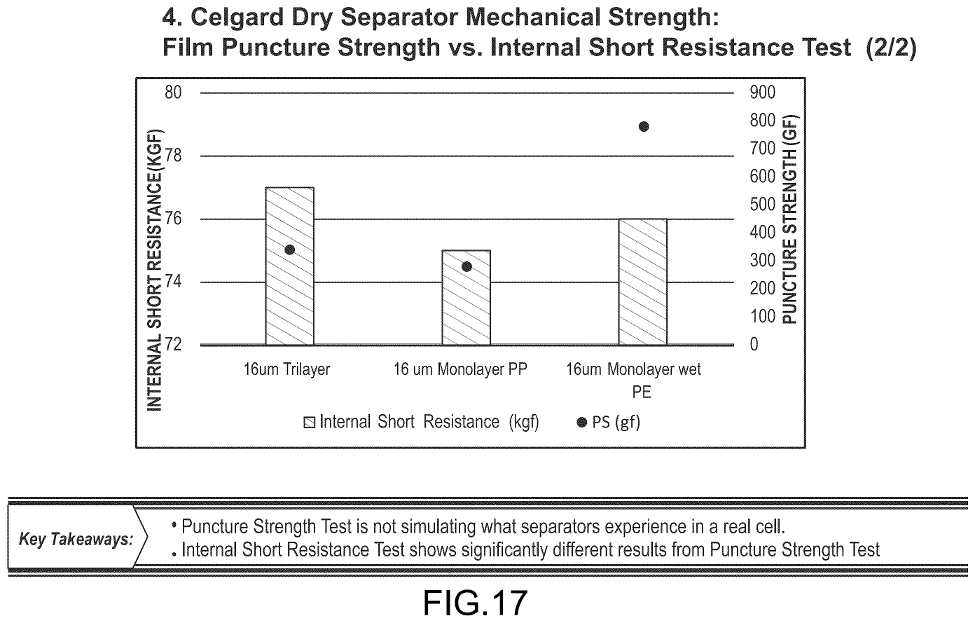

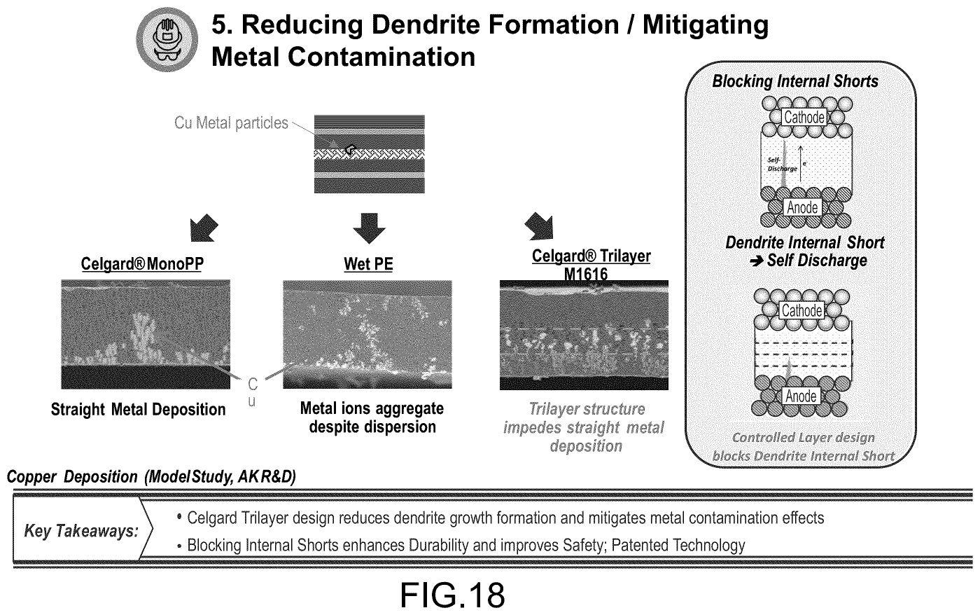

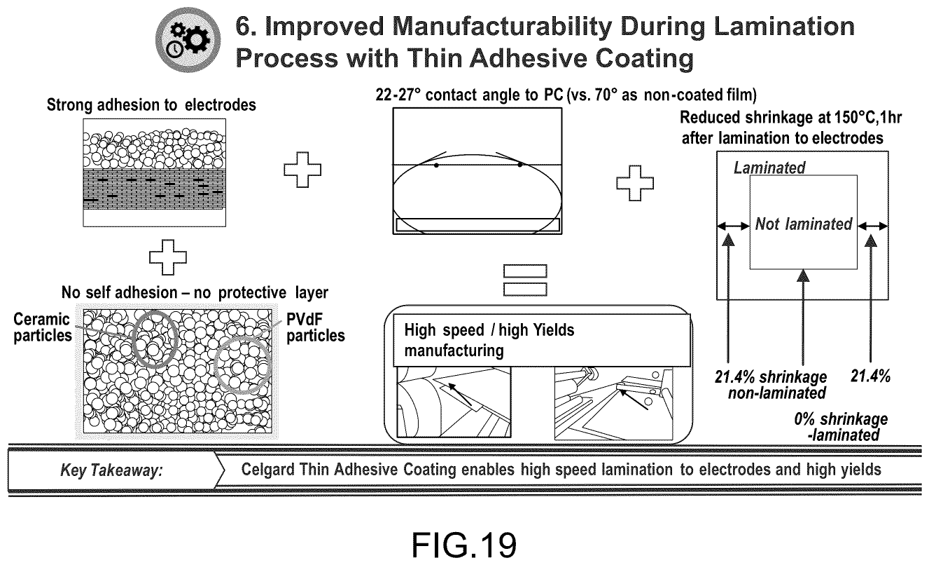

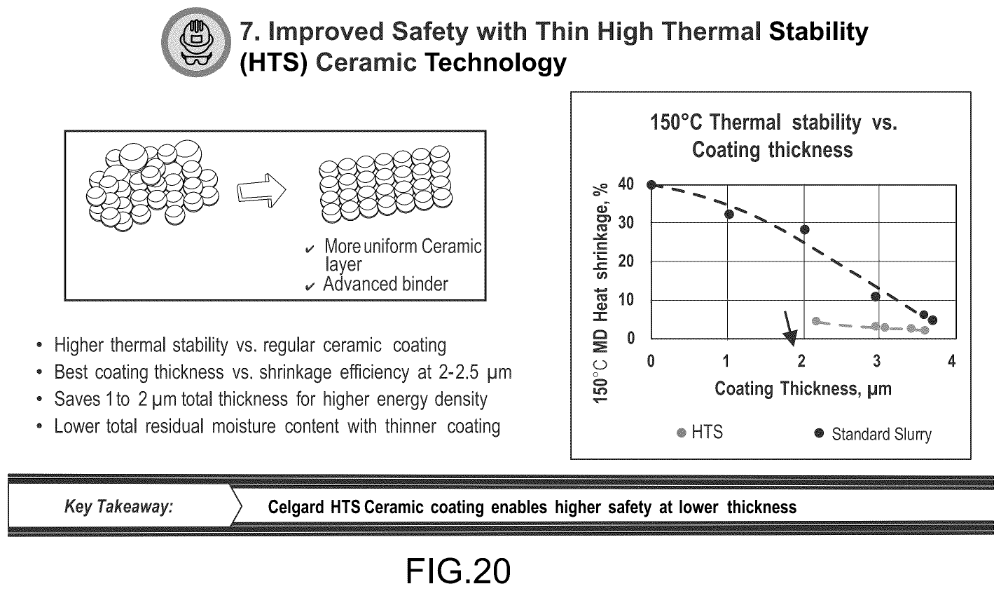

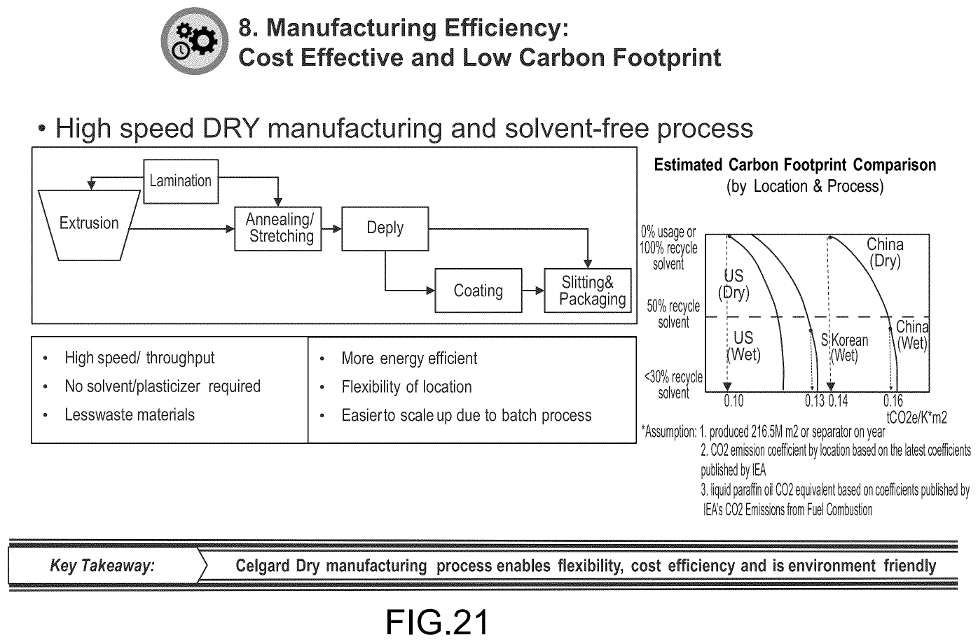

In another testing set, the separator of Sample 6 was tested with respect to electrical resistance and pressure-based properties. Sample 6 was constructed as a dry-process, multilayer PE/PP/PP membrane structure with a two micrometer cross-linked coating on at least one surface thereof. In this test set, a comparative separator constructed as a wet-process PE membrane with a ceramic coating was used as a baseline. Sample 6 and the comparative sample were tested using wet electrical resistance (ER) under a compression test. For this testing set, separators were cut into 80 mm round circles and stacked to form an approximately 2.5 mm thick stack which was placed in a compression die fixture. Next, 3 mL of electrolytes or electrolyte solution were added into the die fixture to wet the stack thoroughly. The compression die fixture was then coupled with a measurement sensor (e.g. Solartron Metrology measurement sensor) for impedance analysis at different loads. Accordingly, a series of loads or load changes were applied to the stack, as well as a set of frequencies. The load changes were applied as follows as a sequential order: 0 lbs, 1,000 lbs, 0 lbs, 2,000 lbs, 0 lbs, 5,000 lbs, 0 lbs, 7,500 lbs, 0 lbs, 10,000 lbs. A waiting time was used between each load change and was set to 30 seconds. The frequency of the response test was set to a range of 105 Hz to 0.1 Hz, and a disturb voltage was set to 5 mV. FIG. 5 illustrates the results of this testing set, where ohmic, electrical resistance (ER) was measured (normalized by separator thickness) as a function of compression pressure. As seen in FIG. 8, the dry-process separator of sample 6 exhibits smaller increases in electrical resistance (ER) under pressure than the comparison sample. In some example instances, the increases in ER can be 30% lower. It will be appreciated that this testing set illustrates the advantages of battery separators or membranes as described herein as implemented in a battery or cell. For example, when electrical resistance in a battery or cell increases, lithium ion deposition occurs more easily and in turn the growth of lithium dendrites occurs more easily. Therefore, with respect to separators or membranes, lower increases in ER under pressure is a desirable property, and particularly important in cylindrical cells where pressure is higher than in other cells.

In accordance with at least certain embodiments, aspects, or objects of the present disclosure or invention, shown, described, claimed, or provided are new or improved films, thin films, membranes, dry process polyolefin membranes, coated membranes, separators, coated separators, batteries and/or cells, lithium batteries and/or cells, battery and/or cell components, and/or methods or devices for making, testing, and/or using the same.

In at least one aspect, a method of measuring the internal short resistance of a battery separator comprising one or more layers of a polyolefin is provided. A preferred method comprises applying a force via a force component comprising a ball to a test stack, the test stack comprising an anode, a separator, and a cathode, deforming the test stack until an electrical short occurs, and determining an ISR value for the separator, the value corresponding to an overall ISR, or at least in one of the MD, TD, or Z-direction.

Unfortunately, many current lithium battery separator tests are from the textile industry, NOT from real battery needs. Although there are many published methods to study battery separators, the inventive concept is the big deviation of separator impact on battery safety and battery performance and in at least a preferred embodiment may rely on:
A new ISR test of the force required to create a short through a separator due to Internal Short Resistance (Electrode Short).
It measures the strength of separator and resistance towards Electrode penetration.
It simulates the behavior of real cell. It is more closely related to particle penetration resistance compared to puncture resistance.
Internal Short Resistance strength is used to indicate the tendency of separators to allow short-circuits during battery performance and tests.
The preferred Ball is harder than the Steel Strip (and may dent the steel strip during testing. Ball sizes may range from 0.01 inch to 10 inches, preferably 0.25 inch to 5 inches, or more preferably from 0.5 inch to 3 inches in diameter.
For each new new test cycle, the Platform is indexed to a new location as the stack is deformed under the ball during each test.

Membranes that are compressible and elastic may be most preferred. For example, membranes that can compress more than 5% and recovers nearly 100% after pressure is removed. This is ideal in a battery that includes electrodes that swells and contracts. The separator should be able to handle pressure exerted thereon by the swelling electrode, and should be able to return to it's original thickness when the pressure subsides. If, after being compressed due to swelling of the electrodes, the separator does not return to it's original thickness, a gap may be left between the separator and the electrodes. Gaps provide areas for dendrites to grow, and dendrites can lead to short circuits of the battery, and explosions. Separator Function (per customer request or product specification, or per Celgard recommendation based on battery technology):
1. electronically (insulator) separate two electrodes
2. soaking or no-soaking liquid electrolytes to provide ionic conduction
3. provide maximum energy density for batteries by reduction of separator volume (thickness) and weight
4. special functions (Shut Down, Thermal Isolation, etc.)

Therefore, in a battery operating range, the separator needs to be Stable (varies with customer's requirements, battery technology or Celgard recommendation)
1. Mechanical
2. Thermal
3. Chemical
4. Electrochemical
5. Dimensional
6. Special function needs
7. etc.
Separator property varies with particular battery:
chemistry;
cell design;
format;
electrode chemistry and process;
electrolytes and injection method;
battery process, assembly and environment;
performance requirement;
abuse test needs;
normal internal short needs;
etc.

Although there are many published methods to study separators, the inventive concept is the big deviation of separator impact on battery safety and battery performance and may rely on:
1. Separator ionical conduction capability (air permeability is NOT ionic conductivity!)
2. Separator wet (with electrolyte, polymer swells, not shrinks) tests vs many proposed DRY tests (no electrolyte):
   (A) Shrinkage or Swelling in battery NOT in Oven
   (B) Porosity and pore size based on electrolyte swelled separator vs non-swelling test data
(C) Compression Elasticity
(D) Chemical and electrochemical stability with wetted separator in battery (not aging in the air+Oven!)
3. Internal Short Resistance (ISR Z-direction) deformation (internal short resistance) vs Puncture strength and Tensile strength
4. Improved Cathode
5. Combinations of the above.

Unfortunately, many current separator tests are from the textile industry, NOT from real battery needs.

With modern cell design (new electrodes active materials, greatly improved electrode structure, new electrolytes, new cell design, and commonly used VARIOUS ceramic coated separators. Cell (battery) safety mainly rely on:
1. Design experiences
2. Chemistries (Electrodes, Electrolytes, etc.)
3. Various Cell processes and quality controls
4. Application conditions (Mechanical, Thermal, Electrochemical, Abuses, etc.)
5. New inventive tests, ratios, relationships,
6. Etc.
   Physical characteristics:
Air permeability—Air permeability testing is intended to assess a separator material's resistance to the passage of air under a specified pressure. Testing follows the test method detailed in ASTM D726; There is NO air or liquid flow inside the battery (with wetout separator). The real material “flow” in the separator of batteries, is the ion==>ionic conductivity. There is limited or no relationship between ionic conductivity and air permeability for modern separators.
Pore size and distribution—This test determines the size and distribution of pores in the separator material by measuring the pressure and flow rate at which gas flows through the material. The specific test methods used are described in SAE J2983; Frequently less meaningful for modern separators due to the introduction of many separator components such as various PVDF, Solid State Electrolyte, Ceramic binders.
Wettability—Wettability testing measures the time required for separator material to become completely wetted when it comes in contact with electrolyte; testing and measurements specific are described in NASA/TM 2010-216099. Depends on the multi-phase interfaces (the components in electrolyte, cathode, anode, separator, vaccumed residue air, etc.) and the electrolyte injection process (vaccum level, vaccum times, amount of electrolyte/injection, sitting times etc.)

### Mechanical Characteristics

Tensile strength—Tensile strength testing assesses a separator material's resistance to elongation when subject to tension. Tensile strength testing follows the test method described in ASTM D882; More important for separator is Z-directional strength, see following comments on INTERNAL SHORT RESISTANCE.
Puncture strength—Puncture strength testing is intended to assess a material's resistance to penetration from either a sharp object or through blunt force. Testing follows the test method described in ASTM D3763. Puncture test is a test of film sheet tensile strength in X-Y surface (see detailed explanation above). For batteries, more important are the (Z-directional) INTERNAL SHORT RESISTANCE and COMPRESSION ELASTICITY (due to electrode expansion and shrinkage during battery performance).

### Thermal Characteristics

Dimensional stability
   Puncture Strength after Oven Aging—Puncture strength after Oven Aging testing is intended to assess a material's resistance to penetration from either a sharp object or through blunt force after being subjected to the elevated internal temperatures experienced inside a lithium-ion battery. After OVEN aging, the chemical reaction with air or O2 in the OVEN may serious impact the mechanical strength of separator due to chemical reactions, while it will not happen in real batteries (such as PP can be oxidized in the high temperature air while it will NOT happen in batteries).
   Shrinkage after Oven Aging—Shrinkage after oven aging testing assesses a material's ability to resist shrinkage after being subjected to the elevated internal temperatures experienced inside a lithium-ion battery; Most simple base film, contains >50% amorphous polymer, will swell when meet with solvent of electrolyte instead of shrink.
Shutdown temperature—Shutdown temperature testing is designed to evaluate changes in material impedance over a range of temperatures; Changes with cell chemistry, cell design and testing methodology.
Melting temperature—Melting temperature testing assesses the temperature level at which a separator material disintegrates due to heat exposure. Testing follows the test method described in UL 746A (ASTM D3418). Most modern separators are ceramic (Al₂O₃, BaSO4, SiO2 etc.) coated separators and the ceramic content varies with requirement of battery producers, which seriously impacts the melting point of the separators.
Are there other separator tests that should be considered as it relates to potential safety risks and performance. Many, varies with customer cell design.

Many different arrangements of the various components and/or steps depicted and described, as well as those not shown, are possible without departing from the scope of the claims below. Embodiments of the present technology have been described with the intent to be illustrative rather than restrictive. Alternative embodiments will become apparent from reference to this disclosure. Alternative means of implementing the aforementioned can be completed without departing from the scope of the claims below. Certain features and subcombinations are of utility and can be employed without reference to other features and subcombinations and are contemplated within the scope of the claims.

1-23. (canceled)

24. A method of measuring an internal short resistance (ISR) of a battery separator, comprising:
applying a force via a force component comprising a ball to a test stack, the test stack comprising an anode, a separator, and a cathode;
deforming the test stack until an electrical short occurs;
determining an ISR value for the separator.

25. The method of claim 24, wherein the force is applied incrementally.

26. The method of claim 24, wherein the test stack further comprises a steel strip and a platform.

27. The method of claim 26, wherein the platform is indexed to a new location as the test stack is deformed.

28. The method of claim 24, wherein the ball has a diameter from about 0.01 inches to about 10 inches in diameter.

29. The method of claim 28, wherein the ball has a diameter from about 0.5 inches to about 3 inches in diameter.

30. The method of claim 24, wherein the separator comprises one or more layers of a polyolefin.

31. The method of claim 24, wherein the separator is a dry-stretch process microporous membrane.

32. The method of claim 24, wherein the separator is coated.

33. The method of claim 30, wherein the separator comprises one or more polyolefins.

34. The method of claim 30, wherein the polyolefin is polyethylene, polypropylene, or a combination of both.

35. The method of claim 24, wherein the separator is a single layer film, a bilayer film, a trilayer film, or a multilayer film.

36. A wetting test apparatus, comprising:
a chamber comprising an electrolyte injection port;
a pair of conductive blocks within the chamber and biased towards each other via a spring;
a separator stack held between the blocks; and
an impedance device in communication with the conductive blocks.

37. The apparatus of claim 36, wherein the separator stack is configured as anode/separator/anode/separator/anode.

38. The apparatus of claim 36 wherein the separator stack is configured as cathode/separator/cathode/separator/cathode.

39. A method of testing wetting for a batter separator, comprising:
providing an apparatus of claim 36;
releasing electrolyte into the chamber to wet out the separator stack;
determining a frequency associated with the separator stack via the impedance device;
setting the frequency and a voltage; and
determining an impedance associated with the separator stack over a time period.

40. The method of claim 39, comprising altering the pressure between the conductive blocks.

41. The method of claim 39, wherein the separator stack is configured as anode/separator/anode/separator/anode.

42. The method of claim 39, wherein the separator stack is configured as cathode/separator/cathode/separator/cathode.

43. New or improved films, thin films, membranes, dry process polyolefin membranes, coated membranes, separators, coated separators, batteries and/or cells, lithium batteries and/or cells, battery and/or cell components, and/or methods or devices for making, testing, and/or using the same as shown, described, or claimed herein.

44. A new or improved cell, battery, lithium battery, lithium ion battery, or the like made with a battery separator having improved Internal Short Resistance or ISR (Electrode Short behavior) as per the Test as shown or described herein.

45. A new or improved battery separator having improved Internal Short Resistance or ISR (Electrode Short behavior), and having improved Compression Elasticty, ER, and/or Pressure resistance as shown or described herein.

46. The new or improved films, thin films, membranes, dry process polyolefin membranes, coated membranes, separators, coated separators, batteries and/or cells, lithium batteries and/or cells, and/or battery and/or cell components of claim 43 as shown or described in at least one of FIG. 1, 2, 5, 7, 10, 11, 14, 15, 17, 18, 19, or 20 herein.

47. A new or improved cell, battery, lithium battery, lithium ion battery, or the like made with a battery separator of claim 44 as shown or described in at least one of FIG. 1, 2, 5, 7, 10, 11, 14, 15, 17, 18, 19, or 20 herein.

48. A new or improved battery separator of claim 45 as shown or described in at least one of FIG. 1, 2, 5, 7, 10, 11, 14, 15, 17, 18, 19, or 20 herein.
